(19) United States
(12) Patent Application Publication
(10) Pub. No.: US 2010/0283005 A1
(43) Pub. Date: Nov. 11, 2010

(54) NANOPARTICLES AND THEIR MANUFACTURE

(75) Inventors: Nigel Pickett, London (GB); Steven Daniels, Manchester (GB); Imrana Mushtaq, Manchester (GB)

Correspondence Address: GOODWIN PROCTER LLP;PATENT ADMINISTRATOR, 53 STATE STREET, EXCHANGE PLACE, BOSTON, MA, 02109-2881, US

(73) Assignee: NANOCO TECHNOLOGIES LIMITED, Manchester (GB)

(21) Appl. No.: 12/239,254

(22) Filed: Sep. 26, 2008

Related U.S. Application Data
(60) Provisional application No. 60/980,946, filed on Oct. 18, 2007.

(30) Foreign Application Priority Data
Sep. 28, 2007 (GB) 0719073.9
Sep. 28, 2007 (GB) 0719075.4

(51) Int. Cl. C09K 11/70; C09K 11/62; C09K 11/56; C09K 11/54; H01L 33/04; H01L 21/20

(52) U.S. Cl. 252/301.6 S; 252/301.6 P; 252/301.4 P; 252/301.6 R; 257/13; 438/104; 977/773; 977/774; 257/E33.005; 257/E21.09

(57) ABSTRACT

Nanoparticles include or consist essentially of (i) a core that itself includes or consists essentially of a first material, and (ii) a layer including or consisting essentially of a second material. In various embodiments, one of the first and second materials is a semiconductor material incorporating ions from group 13 and group 15 of the periodic table, and the other of the first and second materials is a metal oxide material incorporating metal ions selected from any one of groups 1 to 12, 14 and 15 of the periodic table. In other embodiments, one of the first and second materials is a semiconductor material, and the other of the first and second materials is an oxide of a metal selected from any one of groups 3 to 10 of the periodic table. Methods for preparing such nanoparticles are also described.

### CROSS-REFERENCE TO RELATED APPLICATIONS

This application claims priority to and the benefit of, and incorporates herein by reference in their entireties, U.S. Provisional Patent Application No. 60/980,946, filed on Oct. 18, 2007; U.K. Patent Application No. 0719073.9, filed on Sep. 28, 2007; and U.K. Patent Application No. 0719075.4, filed on Sep. 28, 2007.

### FIELD OF THE INVENTION

The present invention relates to semiconductor nanoparticles and techniques for their production.

### BACKGROUND

There has been substantial interest in the preparation and characterisation of compound semiconductors comprising particles with dimensions, for example in the range 2-50 nm, often referred to as ‘quantum dots’ or nanocrystals. These studies have occurred mainly due to the size-tuneable electronic properties of these materials that may be exploited in many commercial applications such as optical and electronic devices and other applications that now range from biological labelling, solar cells, catalysis, biological imaging, light-emitting diodes, general space lighting and both electroluminescence and photoluminescence displays amongst many new and emerging applications.

The most studied of semiconductor materials have been the chalcogenide II-VI (i.e., group 12-group 16 of the periodic table) materials, such as ZnS, ZnSe, CdS, CdSe and CdTe. CdSe has been greatly studied due to its optical tuneability over the visible region of the spectrum. Although some earlier examples appear in the literature, more recently, reproducible methods have been developed from “bottom up” techniques, whereby particles are prepared atom-by-atom using “wet” chemical procedures.

Two fundamental factors, both related to the size of the individual semiconductor nanoparticle, are responsible for the unique properties of these particles. The first is the large surface-to-volume ratio: as a particle becomes smaller, the ratio of the number of surface atoms to those in the interior increases. This leads to the surface properties playing an important role in the overall properties of the material. The second factor is that, with semiconductor nanoparticles, there is a change in the electronic properties of the material with size; for example, the band-gap gradually becomes larger because of quantum confinement effects as the size of the particles decreases. This effect gives rise to discrete energy levels similar to those observed in atoms and molecules, rather than a continuous band as in the corresponding bulk semiconductor material. Thus, for a semiconductor nanoparticle, because of the physical parameters, the “electron and hole”, produced by the absorption of electromagnetic radiation (a photon) with energy greater then the first excitonic transition, are closer together than in the corresponding macrocrystalline material, so that the Coulombic interaction cannot be neglected. This leads to a narrow bandwidth emission, which is dependent upon the particle size and composition. Thus, quantum dots have higher kinetic energy than the corresponding macrocrystalline material and consequently the first excitonic transition (band-gap) increases in energy with decreasing particle diameter.

Single-core semiconductor nanoparticles, which involve a single semiconductor material along with an outer organic passivating layer, may have relatively low quantum efficiencies due to electron-hole recombination occurring at defects and dangling bonds situated on the nanoparticle surface (which lead to non-radiative electron-hole recombinations).

One method to eliminate defects and dangling bonds is to grow a second inorganic material, having a wider band-gap and small lattice mismatch to that of the core material, epitaxially on the surface of the core particle to produce a “core-shell” particle. Core-shell particles separate any carriers confined in the core from surface states that would otherwise act as non-radiative recombination centres. One example is ZnS grown on the surface of a CdSe core to provide a CdSe/ZnS core/shell nanoparticle.

Another approach is to prepare a core/multi-shell structure where the “electron-hole” pair is completely confined to a single shell layer such as the quantum dot-quantum well structure. Here, the core is of a wide bandgap material, followed by a thin shell of narrower bandgap material, and capped with a further wide bandgap layer, such as CdS/HgS/CdS grown using a substitution of Hg for Cd on the surface of the core nanocrystal to deposit just a few monolayers of HgS. The resulting structures exhibited clear confinement of photo-excited carriers in the HgS layer.

The coordination about the final inorganic surface atoms in any core, core-shell or core-multi shell nanoparticle is generally incomplete, with highly reactive atoms that are not fully coordinated leaving “dangling bonds” on the surface of the particle, which may lead to particle agglomeration. This problem is overcome by passivating (capping) the “bare” surface atoms with protecting organic groups.

The outermost layer (capping agent) of organic material or sheath material helps to inhibit particle aggregation and also further protects the nanoparticle from its surrounding chemical environment. It also provides chemical linkage to other inorganic, organic or biological material. In many cases, the capping agent is the solvent in which the nanoparticle preparation is undertaken, and may be a Lewis base compound, or a Lewis base compound diluted in an inert solvent, such as a hydrocarbon, whereby a lone pair of electrons are capable of donor-type coordination to the surface of the nanoparticle.

Important issues concerning the synthesis of high-quality semiconductor nanoparticles include particle uniformity, size distribution, quantum efficiencies, and, for commercial applications, long-term chemical and photostability. Early routes applied conventional colloidal aqueous chemistry, with more recent methods involving the kinetically controlled precipitation of nanocrystallites, using organometallic compounds. Most of the more recent methods are based on the original “nucleation and growth” method described by Murray et al., J. Am. Chem. Soc. 115:8706 (1993) (hereafter “Murray et al.”), the entire disclosure of which is incorporated by reference herein, but use other precursors from that of the organometallic ones originally used, such as oxides (e.g., CdO), carbonates (e.g., MCO₃), acetates (e.g., M(CH₃CO₂)) and acetylacetanates (e.g., M[CH₃COOCH═C(C—)CH₃]₂) in which, for example, M=Cd or Zn.

Murray et al. originally used organometallic solutions of metal-alkyls (R₂M) where M=Cd, Zn, Te; R=Me, Et and tri-n-octylphosphine sulfide/selenide (TOPS/Se) dissolved in tri-n-octylphosphine (TOP). These precursor solutions are injected into hot tri-n-octylphosphine oxide (TOPO) in the temperature range 120-400° C. depending on the material being produced. This produces TOPO-coated/capped semiconductor nanoparticles of II-VI material. The size of the particles is controlled by the temperature, capping agent, concentration of precursor used and the length of time at which the synthesis is undertaken, with larger particles being obtained at higher temperatures, higher precursor concentrations and prolonged reaction times. This organometallic route has advantages, including greater monodispersity and high particle cystallinity, over other synthetic methods. As mentioned, many variations of this method have now appeared in the literature and routinely give good-quality (in terms of both monodispersity and quantum yield) core and core-shell nanoparticles.

Single-source precursors have also proven useful in the synthesis of semiconductor nanoparticle materials of II-VI, as well as other, compound semiconductor nanoparticles. Bis(dialkyldithio-/diseleno-carbamato)cadmium(II)/zinc(II) compounds, M(E₂CNR₂)₂ (where M=Zn or Cd, E=S or Se and R=alkyl), have been used in a similar ‘one-pot’ synthetic procedure, which involved dissolving the precursor in TOP followed by rapid injection into hot tri-n-octylphosphine oxide/tri-n-octylphosphine (TOPO/TOP) above 200° C.

Fundamentally, all of the above procedures rely on the principle of high-temperature particle nucleation, followed by particle growth at a lower temperature. Moreover, to provide a monodispersed ensemble of nanoparticles in the 2-10 nm range, generally there is proper separation of nanoparticle nucleation from nanoparticle growth. This is achieved by rapid injection of a cooler solution of one or both precursors into a hotter coordinating solvent (containing the other precursor if otherwise not present), which initiates particle nucleation. The sudden addition of the cooler solution upon injection subsequently lowers the reaction temperature (the volume of solution added is typically about ⅓ of the total solution) and inhibits further nucleation. Particle growth (being a surface-catalyzed process or via Ostwald ripening depending on the precursors used) continues to occur at the lower temperature, thus nucleation and growth are separated which yields a narrow nanoparticle size distribution. This method works well for small-scale synthesis where one solution may be added rapidly to another while keeping a reasonably homogeneous temperature throughout the reaction. However, on the larger preparative scales needed for commercial applications, whereby large volumes of solution are required to be rapidly injected into one another, a significant temperature differential may occur within the reaction mixture, and this may subsequently lead to an unacceptably large particle size distribution.

Cooney et al., J. Mater. Chem. 7(4):647 (1997) (hereafter “Cooney et al.”), the entire disclosure of which is incorporated by reference herein, used a II-VI molecular cluster, [S₄Cd₁₀(SPh)₁₆] [Me₃NH]₄, to produce II-VI nanoparticles of CdS, which also involved the oxidation of surface-capping SPh⁻ ligands by iodine. This preparative route involved the fragmentation of the majority of the II-VI clusters into ions, which were consumed by the remaining II-VI ([S₄Cd₁₀(SPh)₁₆]⁴⁻) clusters that subsequently grew into II-VI nanoparticles of CdS.

Strouse et al., Chem. Mater. 14:1576 (2002) (hereafter “Strouse et al.”), the entire disclosure of which is incorporated by reference herein, used a similar synthetic approach using II-VI clusters to grow II-VI nanoparticles, but employed thermolysis (lyothermal) rather than a chemical agent to initiate particle growth. Moreover, the single-source precursors ([M₁₀Se₄(SPh)₁₆][X]₄ where X═Li⁺ or (CH₃)₃NH⁺, and M=Cd or Zn) were thermolysised, whereby fragmentation of some clusters occurred followed by particle growth from scavenging of the free M and Se ions, or simply from clusters aggregating together to form, initially, larger clusters, then small nanoparticles, and ultimately, larger nanoparticles.

Both of the Cooney et al. and Strouse et al. methods employed molecular clusters to grow nanoparticles, but used ions from the clusters to grow the larger nanoparticles—either by fragmentation of some clusters or cluster aggregation. In neither case was a separate nanoparticle precursor composition used to provide the ions required to grow the larger nanoparticle on the original molecular cluster. Moreover, neither of these approaches retained the structural integrity of the original individual molecular clusters in the final nanoparticles. Furthermore, it may be seen that both of these methods are limited to forming a II-VI nanoparticle using a II-VI cluster, which is an inevitable consequence of using the material of the molecular clusters to build the larger nanoparticles. This prior work is therefore limited in terms of the range of possible materials that may be produced.

Published International Patent Application Nos. PCT/GB2005/001611 and PCT/GB2006/004003, the entire disclosures of which are incorporated by reference herein, describe methods of producing large volumes of high-quality mono-dispersed quantum dots, which overcome many of the problems associated with earlier small-scale methods. Chemical precursors are provided in the presence of a molecular cluster compound under conditions whereby the integrity of the molecular cluster is maintained and in that way acts as a well-defined prefabricated seed or template to provide nucleation centres that react with the chemical precursors to produce high quality nanoparticles on a sufficiently large scale for industrial application.

An important distinguishing feature of the methods described in PCT/GB2005/001611 and PCT/GB2006/004003 is that conversion of the precursor composition to the nanoparticles is effected in the presence of a molecular cluster compound which retains its structural integrity throughout nanoparticle growth. Identical molecules of the cluster compound act as seeds or nucleation points upon which nanoparticle growth is initiated. In this way, a high temperature nucleation step is not necessary to initiate nanoparticle growth because suitable well-defined nucleation sites are already provided in the system by the molecular clusters. The molecules of the cluster compound act as a template to direct nanoparticle growth. ‘Molecular cluster’ is a term widely understood in the relevant technical field, but for the sake of clarity, it should be understood herein to relate to clusters of three or more metal atoms and their associated ligands of sufficiently well defined chemical structure such that all molecules of the cluster compound possess the same relative molecular formula. Thus the molecular clusters are identical to one another in the same way that one H₂O molecule is identical to another H₂O molecule. By providing nucleation sites which are so much more well defined than the nucleation sites employed in earlier methods, the use of the molecular cluster compound may provide a population of nanoparticles that are essentially monodispersed. A further significant advantage of this method is that it may be more easily scaled up.

There is great interest in bi-functional and multi-functional nano-scale materials. While a few examples of such materials are known, such as nanoparticles of different compositions fused together to form heterostructures of interlinked nanoparticles (see FIG. 1), there are still relatively few reports of the successful fabrication and exploitation of such materials.

### SUMMARY

An aim of an embodiment of the present invention is to provide nanoparticle materials exhibiting increased functionality. A further aim of an embodiment of the present invention is to provide nanoparticles that are more robust and/or exhibit enhanced optical properties.

In a first aspect, the invention provides a nanoparticle comprising a core that itself comprises a first material and a layer comprising a second material, wherein one of the first and second materials is a semiconductor material incorporating ions from group 13 and group 15 of the periodic table and the other of the first and second materials is a metal oxide material incorporating metal ions selected from any one of groups 1 to 12, 14 and 15 of the periodic table.

In a second aspect, the invention provides a method for producing a nanoparticle comprising a core that itself comprises a first material and a layer comprising a second material, wherein one of the first and second materials is a semiconductor material incorporating ions from group 13 and group 15 of the periodic table and the other of the first and second materials is a metal oxide material incorporating metal ions selected from any one of groups 1 to 12, 14 and 15 of the periodic table, the method comprising forming the core and forming (e.g., depositing) the layer comprising the second material.

In a third aspect, the invention provides a nanoparticle comprising a core that itself comprises a first material and a layer comprising of a second material, wherein one of the first and second materials is a semiconductor material and the other of the first and second materials is an oxide of a metal selected from any one of groups 3 to 10 of the periodic table.

In a fourth aspect, the invention provides a method for producing a nanoparticle comprising a core that itself comprises a first material and a layer comprising a second material, wherein one of the first and second materials is a semiconductor material and the other of the first and second materials is an oxide of a metal selected from any one of groups 3 to 10 of the periodic table, the method comprising forming the core and forming (e.g., depositing) the layer comprising the second material.

These aspects of the invention provide semiconductor/metal oxide core/shell quantum dots and related materials, and methods for producing the same. Embodiments of the invention provide semiconductor-metal oxide nanoparticle materials, and include compound semiconductor particles otherwise referred to as quantum dots or nanocrystals, within the size range 2-100 nm. The nanoparticle materials according to the first aspect of the present invention may be more robust than non-metal-oxide-containing nanoparticles to their surrounding chemical environment, and in some cases have additional properties that are desirable or required in many commercial applications such as paramagnetism.

The semiconductor material, e.g., the III-V semiconductor material, and metal oxide material may be provided in any desirable arrangement, e.g., the nanoparticle core material may comprise the metal oxide material and one or more shells or layers of material grown on the core may comprise the semiconductor material, e.g., the III-V semiconductor material. Alternatively, the nanoparticle core may comprise the semiconductor material, e.g., the III-V semiconductor material, and the outer shell or at least one of the outer shells (where more than one is provided) may comprise the metal oxide material.

In an embodiment, the first material is the III-V semiconductor material and the second material is the oxide of a metal from any one of groups 1 to 12, 14 and 15 of the periodic table. The metal oxide material may be provided as a layer between an inner inorganic core comprising or consisting essentially of the III-V semiconductor material and an outermost organic capping layer.

In another embodiment, the first material is the semiconductor material and the second material is the oxide of a metal selected from groups 3 to 10 of the periodic table. The metal oxide material may be provided as a layer between an inner inorganic core or layer and an outermost organic capping layer.

Any of a number of metal and metal oxide precursors may be employed to form a shell comprising a metal oxide material, e.g., in which the metal is taken from any one of groups 1 to 12, 14 and 15 of the periodic table, grown on a semiconductor nanoparticle core or core/shell resulting in a quantum dot/metal oxide core/shell nanoparticle, a quantum dot inorganic core and shell provided with an outer metal oxide layer, or a core/multi-shell quantum dot provided with an outer metal oxide shell. The outer metal oxide layer may enhance the photostability and chemical stability of the nanoparticle and may therefore render the nanoparticle resistant to fluorescence quenching and/or its surrounding chemical environment. Through use of an oxide as the outer layer, if the nanoparticles reside in an oxygen-containing environment, very little or no further oxidation typically occurs.

In various embodiments of the present invention there are provided core/shell and core/shell/shell nanoparticles comprising a quantum dot core and metal oxide shell or a quantum dot core/shell structure with an outer metal oxide shell. In some preferred embodiments of the present invention there are provided core/shell and core/shell/shell nanoparticles comprising a quantum dot core and metal oxide shell, in which the metal is taken from any one of groups 1 to 12, 14 and 15 of the periodic table, or a quantum dot core/shell structure with an outer metal oxide shell, in which the metal is taken from any one of groups 1 to 12, 14 and 15 of the periodic table. The combination of the luminescence of the core and metal oxide shell are well-suited to applications such as biological, displays, lighting, solar cells and contrast imaging. The preparation of core/shell semiconductor nanoparticles with an outer layer of metal oxide, e.g., in which the metal is taken from any one of groups 1 to 12, 14 and 15 of the periodic table, improves the luminescent properties of the semiconductor core material and makes them more stable against their surrounding chemical environment, i.e., reduces photo-oxidation at the surface or interface of the materials. This enhanced stability is important for many commercial applications. There is also the added desirability of the particles being bi-functionalm, i.e., having both luminescence and paramagnetic properties, in some cases.

With regard to the method of forming, formation of the core may comprise effecting conversion of a nanoparticle core precursor composition to the material of the nanoparticle core. The nanoparticle core precursor composition preferably comprises first and second core precursor species containing the ions to be incorporated into the growing nanoparticle core.

The first and second core precursor species may be separate entities contained in the core precursor composition, and conversion may be effected in the presence of a molecular cluster compound under conditions permitting seeding and growth of the nanoparticle core.

The first and second core precursor species may be combined in a single entity contained in the core precursor composition. The semiconductor material may incorporate ions selected from at least one of groups 2 to 16 of the periodic table.

Formation of the layer comprising the second material preferably comprises effecting conversion of a second material precursor composition to the second material. The second material precursor composition may comprise third and fourth ions to be incorporated into the layer comprising the second material. The third and fourth ions may be separate entities contained in the second material precursor composition, or may be combined in a single entity contained in the second material precursor composition.

In some embodiments, the first material is the semiconductor material and the second material is the metal oxide. The second material precursor composition may comprise the metal ions and the oxide ions to be incorporated into the layer comprising the metal oxide. The second material precursor composition may contain a molecular complex comprising metal cations and N-nitrosophenylhydroxylamine anions. The metal may be selected from group 8 (VIII) of the periodic table, e.g., iron.

In some other embodiments, the first material is the semiconductor material incorporating ions from groups 13 and 15 of the periodic table and the second material is the metal oxide, in which the metal is taken from any one of groups 1 to 12, 14 and 15 of the periodic table. The second material precursor composition may comprise the metal ions and the oxide ions to be incorporated into the layer comprising the metal oxide. The second material precursor composition may contain a metal carboxylate compound comprising metal ions to be incorporated into the layer comprising the metal oxide material and the conversion may comprise reacting the metal carboxylate compound with an alcohol compound. The metal may be selected from group 8 (VIII) of the periodic table, and may, for example, be iron. In some embodiments the metal is selected from group 12 (IIB) of the periodic table, e.g., zinc.

In a fifth aspect, the invention provides a method for the production of a nanoparticle comprising a core that itself comprises a first material and a layer comprising a second material, wherein one of the first and second materials is a semiconductor material incorporating ions from group 13 and group 15 of the periodic table and the other of the first and second materials is a metal oxide material. The method comprises forming the core and forming the layer comprising the second material, wherein formation of the core comprises effecting conversion of a nanoparticle core precursor composition to the material of the nanoparticle core, and the core precursor composition comprises separate first and second core precursor species containing the ions to be incorporated into the growing nanoparticle core. The conversion is effected in the presence of a molecular cluster compound under conditions permitting seeding and growth of the nanoparticle core.

Formation of the layer comprising the second material preferably comprises effecting conversion of a second material precursor composition to the second material. It is preferred that the second material precursor composition comprise third and fourth ions to be incorporated into the layer comprising the second material. The third and fourth ions may be separate entities contained in the second material precursor composition, or the third and fourth ions may be combined in a single entity contained in the second material precursor composition.

The first material may be the semiconductor material incorporating ions from groups 13 and 15 of the periodic table and the second material may be the metal oxide. The second material precursor composition may comprise the metal ions and the oxide ions to be incorporated into the layer comprising the metal oxide. In various embodiments the second material precursor composition contains a metal carboxylate compound comprising metal ions to be incorporated into the layer comprising the metal oxide material and the conversion comprises reacting the metal carboxylate compound with an alcohol compound.

In a sixth aspect, the invention provides a method for producing a nanoparticle comprising a core comprising a semiconductor material incorporating ions from group 13 and group 15 of the periodic table and a layer comprising a metal oxide material. The method comprises forming the core and then forming the layer by effecting conversion of a metal oxide precursor composition to the metal oxide material. The metal oxide precursor composition contains a metal carboxylate compound comprising metal ions to be incorporated into the layer comprising the metal oxide and the conversion comprises reacting the metal carboxylate compound with an alcohol compound.

The metal oxide precursor composition comprises oxide ions to be incorporated into the layer comprising the metal oxide. The oxide ions may be derived from the metal carboxylate compound, or alternatively, from a source other than the metal carboxylate compound.

Formation of the core may comprise effecting conversion of a nanoparticle core precursor composition to the material of the nanoparticle core. The nanoparticle core precursor composition may comprise first and second core precursor species containing the group 13 ions and group 15 ions to be incorporated into the growing nanoparticle core. The first and second core precursor species may be separate entities contained in the core precursor composition, and the conversion may be effected in the presence of a molecular cluster compound under conditions permitting seeding and growth of the nanoparticle core. Alternatively, the first and second core precursor species may be combined in a single entity contained in the core precursor composition.

The carboxylate moiety of the metal carboxylate compound may comprise 2 to 6 carbon atoms, and may be, for example, a metal acetate compound. The alcohol may be a C₆-C₂₄ linear or branched alcohol compound, more preferably a linear saturated C₁₂-C₂₀ alcohol, and most preferably an alcohol selected from the group consisting of 1-heptadecanol, 1-octadecanol and 1-nonadecanol. In various embodiments the reaction of the metal carboxylate compound and the alcohol yields the metal oxide material of the nanoparticle layer.

With regard to the second, fifth and sixth aspects of the invention, the metal may be selected from group 8 of the periodic table, in which case the metal may be iron, or the metal may be selected from group 12 of the periodic table, in which case it may be zinc.

In one embodiment a seeding II-VI molecular cluster is placed in a solvent (coordinating or non-coordinating) in the presence of nanoparticle precursors to initiate particle growth. The seeding molecular cluster is employed as a template to initiate particle growth from other precursors present within the reaction solution. The molecular cluster to be used as the seeding agent may either be prefabricated or produced in-situ prior to acting as a seeding agent. Some precursor may or may not be present at the beginning of the reaction process along with the molecular cluster, however, as the reaction proceeds and the temperature is increased, additional amounts of precursors may be added periodically to the reaction either dropwise as a solution or as a solid.

In accordance with various methods described herein, a nanoparticle precursor composition is converted to a desired nanoparticle. Suitable precursors include single-source precursors in which the two or more ions to be incorporated in to the growing nanoparticle, or multi-source precursors having two or more separate precursors each of which contains at least one ion to be included in the growing nanoparticle. The total amount of precursor composition required to form the final desired yield of nanoparticles may be added before nanoparticle growth has begun, or alternatively, the precursor composition may be added in stages throughout the reaction.

The conversion of the precursor to the material of the nanoparticles may be conducted in any suitable solvent. It will be appreciated that it is typically important to maintain the integrity of the molecules of the cluster compound. Consequently, when the cluster compound and nanoparticle precursor are introduced in to the solvent, the temperature of the solvent is generally sufficiently high to ensure satisfactory dissolution and mixing of the cluster compound—it is not necessary that the present compounds are fully dissolved but desirable—but not so high as to disrupt the integrity of the cluster compound molecules. Once the cluster compound and precursor composition are sufficiently well dissolved in the solvent, the temperature of the solution thus formed is raised to a temperature, or range of temperatures, which is/are sufficiently high to initiate nanoparticle growth but not so high as to damage the integrity of the cluster compound molecules. As the temperature is increased, further quantities of precursor are added to the reaction in a dropwise manner or as a solid. The temperature of the solution may then be maintained at this temperature or within this temperature range for as long as required to form nanoparticles possessing the desired properties.

A wide range of appropriate solvents is available. The particular solvent used is usually at least partly dependent upon the nature of the reacting species, i.e., the nanoparticle precursor and/or cluster compound, and/or the type of nanoparticles to be formed. Typical solvents include Lewis base-type coordinating solvents, such as a phosphine (e.g., TOP), a phosphine oxide (e.g., TOPO) an amine (e.g., HDA), a thiol such as octanethiol or non-coordinating organic solvents, e.g., alkanes and alkenes. If a non-coordinating solvent is used, it will usually be used in the presence of a further coordinating agent to act as a capping agent. This is because, if the nanoparticles being formed are intended to function as quantum dots, it is important that the surface atoms which are not fully coordinated “dangling bonds” are capped to minimise non-radiative electron-hole recombinations and inhibit particle agglomeration, which may lower quantum efficiencies or form aggregates of nanoparticles. A number of different coordinating solvents are known which may also act as capping or passivating agents, e.g., TOP, TOPO, had or long chain organic acids such as myristic acid (tetradecanoic acid), long chain amines (as depicted in FIG. 2), functionalised PEG (polyethylene glycol) chains but not restricted to these capping agents.

If a solvent that cannot act as a capping agent is chosen, then any desirable capping agent may be added to the reaction mixture during nanoparticle growth. Such capping agents are typically Lewis bases, including mono- or multi-dentate ligands of the type phosphines (trioctylphosphine, triphenolphosphine, t-butylphosphine), phosphine oxides (trioctylphosphine oxide), alkyl phosphonic acids, alkyl-amines (e.g., hexadecylamine, octylamine (see FIG. 2)), aryl-amines, pyridines, octanethiol, a long chain fatty acid and thiophenes, but a wide range of other agents are available, such as oleic acid and organic polymers which form protective sheaths around the nanoparticles. With reference to FIG. 2 in which a tertiary amine containing higher alkyl groups is depicted, the amine head groups generally have a strong affinity for the nanocrystals and the hydrocarbon chains help to solubilise and disperse the nanocrystals in the solvent.

The outermost layer (capping agent) of a quantum dot may also comprise or consist essentially of a coordinated ligand that possesses additional functional groups that may be used as chemical linkage to other inorganic, organic or biological material, whereby the functional group points away from the quantum dot surface and is available to bond/react with other available molecules, such as, for example, primary, secondary amines, alcohols, carboxylic acids, azides, hydroxyl group. The outermost layer (capping agent) of a quantum dot may also comprise or consist essentially of a coordinated ligand that possesses a functional group that is polymerisable and may be used to form a polymer around the particle.

The outermost layer (capping agent) may also comprise or consist essentially of organic units that are directly bonded to the outermost inorganic layer and may also possess a functional group, not bonded to the surface of the particle, that may be used to form a polymer around the particle, or for further reactions.

The first aspect of the invention concerns semiconductor nanoparticles incorporating a III-V semiconductor material and a metal oxide material, in which the metal is taken from any one of groups 1 to 12, 14 and 15 of the periodic table. It will be appreciated that the methods representing the fifth and sixth aspects of the present invention are directed to forming nanoparticles incorporating a III-V semiconductor material and any type of metal oxide material. In one method for producing the nanoparticles, molecular clusters, for example, II-VI molecular clusters may be employed in, e.g., the methods representing the second, fifth and sixth aspects of the invention, whereby the clusters are well defined identical molecular entities, as compared to ensembles of small nanoparticles, which inherently lack the anonymous nature of molecular clusters. II-VI molecular clusters may be used to grow cores comprising II-VI or non-II-VI semiconductor materials (e.g., III-V materials, such as InP) as there is a large number of II-VI molecular clusters that may be made by simple procedures and which are not air and moisture sensitive, as is typically the case with III-V clusters. Use of a molecular cluster typically obviates the need for a high-temperature nucleation step as in the conventional methods of producing quantum dots, which means large-scale synthesis is possible.

Moreover, it is possible to use a II-VI molecular cluster, such as [HNEt₃]₄[Zn₁₀S₄(SPh)₁₆], to seed the growth of III-V nanoparticle materials such as InP and GaP quantum dots and their alloys. Following addition or formation in situ of the II-VI molecular cluster, molecular sources of the III and V ion (i.e., “molecular feedstocks”) are added and consumed to facilitate particle growth. These molecular sources may be periodically added to the reaction solution so as to keep the concentration of free ions to a minimum whilst maintaining a concentration of free ions to inhibit Ostwald's ripening from occurring and defocusing of nanoparticle size range from occurring.

Nanoparticle growth may be initiated by heating (thermolysis) or by solvothermal means. The term solvothermal is used herein to refer to heating in a reaction solution so as to initiate and sustain particle growth, and is intended to encompass the processes which are also sometimes referred to as thermolsolvol, solution-pyrolysis, and lyothermal. Particle preparation may also be accomplished by a chemical reaction, i.e., by changing the reaction conditions, such as adding a base or an acid, elevation of pressures, i.e., using pressures greater than atmospheric pressure, application of electromagnetic radiation, such as microwave radiation or any one of a number of other methods known to the skilled person.

Once the desired nanoparticle cores are formed, at least one shell layer is grown on the surface of each core to provide the nanoparticles. Alternatively, once the desired nanoparticle cores are formed, at least one shell layer may be grown on the surface of each core. Any suitable method may be employed to provide the shell layer(s).

In an aspect, embodiments of the invention feature a nanoparticle including a core that includes or consists essentially of a first material and, thereover, a layer that includes or consists essentially of a second material. One of the first and second materials is a semiconductor material incorporating ions from group 13 and group 15 of the periodic table, and the other of the first and second materials is a metal oxide material incorporating metal ions selected from any of groups 1-15 of the periodic table. The metal oxide material may incorporate metal ions selected from any of groups 1-12, 14, and 15 of the periodic table. The metal ions may comprise or consist essentially of iron, and the resulting iron oxide may have a formula selected from the group consisting of FeO, Fe₂O₃, and Fe₃O₄. The iron oxide may be γ-Fe₂O₃. The first material may be the semiconductor material and the second material may be the metal oxide material.

The group 13 ions incorporated in the semiconductor material may be selected from the group consisting of boron, aluminium, gallium, and indium. The group 15 ions incorporated in the semiconductor material may be selected from the group consisting of phosphide, arsenide, and nitride.

The nanoparticle may include a layer comprising or consisting essentially of a third material, the layer disposed between the nanoparticle core and the layer comprising or consisting essentially of the second material. The third material may be a semiconductor material incorporating ions selected from at least one of groups 2-16 of the periodic table.

In another aspect, embodiments of the invention feature a method for producing a nanoparticle that includes a core that includes or consists essentially of a first material and, thereover, a layer that includes or consists essentially of a second material. One of the first and second materials is a semiconductor material incorporating ions from group 13 and group 15 of the periodic table and the other of the first and second materials is a metal oxide material incorporating metal ions selected from any one of groups 1 to 12, 14 and 15 of the periodic table. The method includes forming the core and, thereover, forming the layer including or consisting essentially of the second material.

Formation of the core may include (i) effecting conversion of a nanoparticle core precursor composition to the composition of the nanoparticle core, and (ii) growing the core. The precursor composition may include or consist essentially of first and second core precursor species containing ions to be incorporated into the growing nanoparticle core. The first and second core precursor species may be separate entities in the core precursor composition, and the conversion may be effected in the presence of a molecular cluster compound under conditions permitting seeding and growth of the nanoparticle core. The first and second core precursor species may be combined in a single entity contained in the core precursor composition.

Formation of the layer including or consisting essentially of the second material may include effecting conversion of a second material precursor composition to the second material. The second material precursor composition may include or consist essentially of third and fourth ions to be incorporated into the layer including or consisting essentially of the second material. The third and fourth ions may be separate entities contained in the second material precursor composition, or may be combined in a single entity contained in the second material precursor composition.

The first material may be the semiconductor material incorporating ions from groups 13 and 15 of the periodic table and the second material may be the metal oxide. The second material precursor composition may include or consist essentially of the metal ions and the oxide ions to be incorporated into the layer including or consisting essentially of the metal oxide. The second material precursor composition may include or consist essentially of a metal carboxylate compound comprising metal ions to be incorporated into the layer including or consisting essentially of the metal oxide material, and the conversion may include or consist essentially of reacting the metal carboxylate compound with an alcohol compound.

The metal may be selected from group 8 of the periodic table, and may include or consist essentially of iron. The metal may be selected from group 12 of the periodic table, and may include or consist essentially of zinc.

In yet another aspect, embodiments of the invention feature a nanoparticle including or consisting essentially of a core that includes or consists essentially of a first material, and, thereover, a layer that includes or consists essentially of a second material. One of the first and second materials is a semiconductor material, and the other of the first and second materials is a metal oxide material incorporating metal ions selected from any one of groups 1-12, 14, and 15 of the periodic table. The metal may be selected from any of groups 5-10, 6-9, or 7-9 of the periodic table. The metal may be selected from group 8 of the periodic table, and may be selected from the group consisting of iron, ruthenium, and osmium. The metal may comprise or consist essentially of iron, and the iron oxide may have a formula selected from the group consisting of FeO, Fe₂O₃, and Fe₃O₄. The iron oxide may be γ-Fe₂O₃.

Embodiments of the invention may feature one or more of the following. The semiconductor material may incorporate ions selected from at least one of groups 2-16 of the periodic table. The ions may include or consist essentially of at least one member of the group consisting of magnesium, calcium, and strontium. The ions may include or consist essentially of at least one member of the group consisting of zinc, cadmium, and mercury. The ions may include or consist essentially of at least one member of the group consisting of boron, aluminium, gallium, and indium. The ions may include or consist essentially of at least one member of the group consisting of lead and tin. The ions may include or consist essentially of at least one member of the group consisting of sulfur, selenium, and tellurium. The ions may include or consist essentially of at least one member of the group consisting of phosphide, arsenide, and nitride. The ions may include or consist essentially of carbide ions.

The semiconductor material may include or consist essentially of ions selected from the group consisting of ions from the transition metal group of the periodic table and ions from the d-block of the periodic table. The nanoparticle may include a layer including or consisting essentially of a third material disposed between the nanoparticle core and the layer including or consisting essentially of the second material. The first material may be the semiconductor material and the second material may be the metal oxide.

In a further aspect, embodiments of the invention feature a method for producing a nanoparticle including or consisting of a core that includes or consists essentially of a first material, and, thereover, a layer that includes or consists essentially of a second material. One of the first and second materials is a semiconductor material, and the other of the first and second materials is an oxide of a metal selected from any of groups 3-10 of the periodic table. The method includes forming the core and depositing, on the core, the layer including or consisting essentially of the second material.

Formation of the core may include or consist essentially of (i) effecting conversion of a nanoparticle core precursor composition to the composition of the nanoparticle core, and (ii) growing the core. The precursor composition may include or consist essentially of first and second core precursor species containing ions to be incorporated into the growing nanoparticle core. The first and second core precursor species may be separate entities in the core precursor composition, and the conversion may be effected in the presence of a molecular cluster compound under conditions permitting seeding and growth of the nanoparticle core. The first and second core precursor species may be combined in a single entity contained in the core precursor composition.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF FIGURES

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic representation of a prior art iron oxide core nanoparticle linked to a plurality of CdS nanoparticles;

FIG. 2 is a schematic representation of a nanoparticle coated with octylamine capping agent;

FIG. 3 is a schematic representation of, a) a particle consisting of a semiconductor core only, b) a particle having a semiconductor core and metal-oxide shell in accordance with a preferred embodiment of the present invention, and c) a particle having a semiconductor core, a buffer layer of a different semiconductor material and an outer metal-oxide shell in accordance with a further preferred embodiment of the present invention;

FIG. 4 is a schematic representation of a semiconductor/metal oxide (InP/Fe₂O₃) core/shell nanoparticle according to a preferred embodiment of the present invention prepared as described below in Example 3;

FIG. 5 shows photoluminescence spectra of InP and InP/In₂O₃ nanoparticles produced according to Example 4;

FIG. 6 shows photoluminescence spectra of CdSe/γ-Fe₂O₃ nanoparticles according to a further preferred embodiment of the first aspect of the present invention with increasing Fe₂O₃ shell thickness prepared as described below in Example 7; and

FIG. 7 shows x-ray diffraction patterns of the CdSe/γ-Fe₂O₃ core/shell nanoparticles prepared according to Example 7 (top line) and CdSe nanoparticles (bottom line);

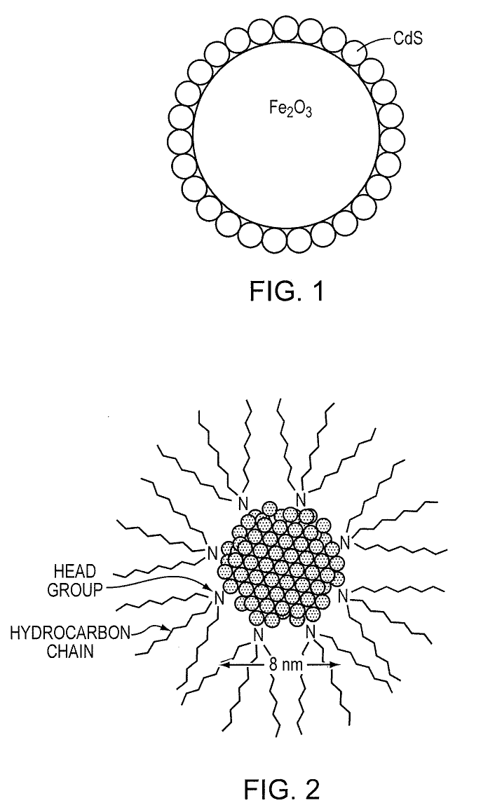

### DETAILED DESCRIPTION

Feedstocks

These molecular feedstocks may be in the form of a single-source precursor whereby all elements required within the nanoparticle are present within a single compound precursor, or a combination of precursors each containing one or more element/ion species required within the nanoparticles. These feedstocks may be added at the beginning of the reaction or periodically throughout the reaction of particle growth, and may be in the form of liquids, solutions, solids, slurries or gases.

Type of System to be Made

In some embodiments, the invention involves preparation of nanoparticulate materials incorporating a III-V semiconductor material (that is, a semiconductor material incorporating ions from groups 13 and 15 of the periodic table) and certain metal oxide materials, and includes compound semiconductor particles otherwise referred to as quantum dots or nanocrystals within the size range 2-100 nm.

The III-V semiconductor material may be in (or constitute) the core of the nanoparticle, or in one or more of the outer shells or layers of material formed on the nanoparticle core. It is particularly preferred that the III-V material is in the nanoparticle core. The III-V semiconductor material may incorporate group 13 ions selected from the group consisting of boron, aluminium, gallium and indium; and/or group 15 ions selected from the group consisting of phosphide, arsenide and nitride.

The same or a different semiconductor material may form one or more shell layers around the nanoparticle core, subject to the proviso that the nanoparticle material also incorporates a material that is an oxide of a metal.

Nanoparticles in accordance with the invention may further comprise a non-III-V semiconductor material. The non-III-V semiconductor material may incorporate ions selected from at least one of groups 2 to 16 of the periodic table. The non-III-V semiconductor material may be used in one or more shells or layers grown on the nanoparticle core and in most cases will be of a similar lattice type to the material in the immediate inner layer upon which the non-III-V material is being grown, i.e., have close lattice match to the immediate inner material so that the non-III-V material may be epitaxially grown, but is not necessarily restricted to materials of this compatibility.

The non-III-V semiconductor material may incorporate ions from group 2 (IIA) of the periodic table, which may be selected from the group consisting of magnesium, calcium and strontium. The non-III-V semiconductor material may incorporate ions from group 12 (IIB) of the periodic table, such as ions selected from the group consisting of zinc, cadmium and mercury. The non-III-V semiconductor material may incorporate ions from group 14 (IVB), such as lead or tin ions. The non-III-V semiconductor material may incorporate ions from group 16 (VIB) of the periodic table. For example, ions selected from the group consisting of sulfur, selenium and telerium. The non-III-V semiconductor material may incorporate ions from group 14 of the periodic table, by way of example, carbide ions. The non-III-V semiconductor material may incorporate ions selected from the group consisting of ions from the transition metal group of the periodic table or ions from the d-block of the periodic table. The non-III-V semiconductor material may incorporate ions from group 13 (IIIB), for example, ions selected from the group consisting of boron, aluminium, gallium and indium, or ions from group 15 (VB) of the periodic table, such as ions selected from the group consisting of phosphide, arsenide and nitride, subject to the proviso that the non-III-V does not incorporate ions from both group 13 and group 15.

A buffer layer comprising or consisting essentially of a third material may be grown on the outside of the core, between the core and the shell, if, for example, the two materials (core and shell) are incompatible or not sufficiently compatible to facilitate acceptable growth of the shell layer of the second material. The third material may be a semiconductor material incorporating ions from at least one of groups 2 to 16 of the periodic table. The third material may incorporate any of the ions set out above in respect of the non-III-V semiconductor ions and/or may also include ions from both group 13 and group 15 of the periodic table in any desirable combination.

The non-III-V semiconductor material and/or buffer layer of semiconductor material may comprise:
IIA-VIB (2-16) material incorporating a first element from group 2 of the periodic table and a second element from group 16 of the periodic table and also including ternary and quaternary materials and doped materials. Suitable nanoparticle semiconductor materials include but are not restricted to MgS, MgSe, MgTe, CaS, CaSe, CaTe, SrS, SrSe, SrTe.
IIB-VIB (12-16) material incorporating of a first element from group 12 of the periodic table and a second element from group 16 of the periodic table and also including ternary and quaternary materials and doped materials. Suitable nanoparticle semiconductor materials include but are not restricted to ZnS, ZnSe, ZnTe, CdS, CdSe, CdTe, HgS, HgSe, HgTe.
II-V material incorporating a first element from group 12 of the periodic table and a second element from group 15 of the periodic table and also including ternary and quaternary materials and doped materials. Suitable nanoparticle semiconductor materials include but are not restricted to Zn₃P₂, Zn₃As₂, Cd₃P₂, Cd₃As₂, Cd₃N₂, Zn₃N₂.
III-IV material incorporating a first element from group 13 of the periodic table and a second element from group 14 of the periodic table and also including ternary and quaternary materials and doped materials. Suitable nanoparticle semiconductor materials include but are not restricted to B₄C, Al₄C₃, Ga₄C.
III-VI material incorporating a first element from group 13 of the periodic table and a second element from group 16 of the periodic table and also including ternary and quaternary materials. Suitable nanoparticle semiconductor materials include but are not restricted to Al₂S₃, Al₂Se₃, Al₂Te₃, Ga₂S₃, Ga₂Se₃; In₂S₃, In₂Se₃, Ga₂Te₃, In₂Te₃.
IV-VI material incorporating a first element from group 14 of the periodic table and a second element from group 16 of the periodic table and also including ternary and quaternary materials and doped materials. Suitable nanoparticle semiconductor materials include but are not restricted to PbS, PbSe, PbTe, SnS, SnSe, SnTe.
Nanoparticle material incorporating a first element from any group in the transition metal of the periodic table, and a second element from any group of the d-block elements of the periodic table and also including ternary and quaternary materials and doped materials. Suitable nanoparticle semiconductor materials include but are not restricted to NiS, CrS, CuInS₂.

In addition to the above materials, the buffer layer may also comprise:
III-V material incorporating a first element from group 13 of the periodic table and a second element from group 15 of the periodic table and also including ternary and quaternary materials and doped materials. Suitable nanoparticle semiconductor materials include but are not restricted to BP, AlP, AlAs, AlSb; GaN, GaP, GaAs, GaSb; InN, InP, InAs, InSb, AlN, BN.

Nanoparticles according to various aspects of the present invention may incorporate one or more layers of a metal oxide material selected from the following:

+1 Oxidation State

Silver(I)oxide, Ag₂O;

+2 Oxidation State

Aluminium monoxide, AlO; Barium oxide, BaO; Beryllium oxide, BeO; Cadmium oxide, CdO; Calcium oxide, CaO; Cobalt (II) oxide, CoO; Copper (II) oxide, CuO; Iron (II) oxide, FeO; Lead (II) oxide, PbO; Magnesium (II) oxide, MgO; Mercury (II) oxide, HgO; Nickel (II) oxide, NiO; Palladium (II) oxide, PdO; Silver (II) oxide. AgO; Strontium oxide, SrO; Tin oxide, SnO; Titanium (II) oxide, TiO; Vanadium (II)oxide, VO; Zinc oxide, ZnO.

+3 Oxidation State

Aluminium oxide, Al₂O₃; Antimony trioxide, Sb₂O₃; Arsenic trioxide, As₂O₃; Bismuth trioxide, Bi₂O₃; Boron oxide, B₂O₃; Chromium (III) oxide, Cr₂O₃; Erbium (III) oxide, Er₂O₃; Gadolinium (III) oxide, Gd₂O₃; Gallium (III) oxide, Ga₂O₃; Holmium (III) oxide, Ho₂O₃; Indium (III) oxide, In₂O₃; Iron (III) oxide, Fe₂O₃; Lanthanum (III) oxide, La₂O₃; Lutetium (III) oxide, Lu₂O₃; Nickel (III) oxide, Ni₂O₃; Rhodium (III) oxide, Rh₂O₃; Samarium (III) oxide, Sm₂O₃; Scandium (III) oxide, Sc₂O₃; Terbium (III) oxide, Tb₂O₃; Thallium (III) oxide, Tl₂O₃; Thulium (III) oxide, Tm₂O₃; Titanium (III) oxide, Ti₂O₃; Tungsten (III) oxide, W₂O₃; Vanadium (III) oxide, V₂O₃; Ytterbium (III) oxide, Yb₂O₃; Yttrium (III) oxide, Y₂O₃.

+4 Oxidation State

Cerium (IV) oxide, CeO₂; Chromium (IV) oxide, CrO₂; Germanium dioxide, GeO₂; Hafnium (IV) oxide, HfO₂; Lead (IV) oxide, PbO₂; Manganese (IV) oxide, MnO₂; Plutonium (IV) oxide, PuO₂; Ruthenium (IV) oxide, RuO₂; Silicon (IV) oxide, SiO₂; Thorium dioxide, ThO₂; Tin dioxide, SnO₂; Titanium dioxide, TiO₂, Tungsten (IV) oxide, WO₂; Uranium dioxide, UO₂; Vanadium (IV) oxide, VO₂; Zirconium dioxide, ZrO₂.

+5 Oxidation State

Antimony pentoxide, Sb₂O₅; Arsenic pentoxide, As₂O₅; Niobium Pentoxide, Nb₂O₅; Tantalum pentoxide, Ta₂O₅; Vanadium (V) oxide, V₂O₅.

+6 Oxidation State

Chromium trioxide, CrO₃; Molybdenum (VI) oxide, MoO₃; Rhenium trioxide, ReO₃; Tellurium trioxide, TeO₃; Tungsten trioxide, WO₃; Uranium trioxide, UO₃.

+7 Oxidation State

Manganese (VII) oxide, Mn₂O₇; Rhenium (VII) oxide, Re₂O₇.

Mixed Oxides

Indium tin oxide and indium zinc oxide

Concerning the first aspect of the present invention, the metal oxide material(s) of the nanoparticle core and/or any number of shell layers may be an oxide of any metal taken from groups 1 to 12, 14 or 15 of the periodic table.

If selected from group 1 of the periodic table, the metal may be one or more of lithium, sodium or potassium. If selected from group 2 of the periodic table, the metal may be one or more of beryllium, magnesium, calcium, strontium or barium. If selected from group 3 of the periodic table, the metal may be one or more of scandium or yttrium. If selected from group 4 of the periodic table, the metal may be one or more of titanium, zirconium or hafnium.

If selected from group 5 of the periodic table, the metal may be one or more of vanadium, niobium or tantalum. If selected from group 6 of the periodic table, the metal may be one or more of chromium, molybdenum or tungsten. If selected from group 7 of the periodic table, the metal may be one or more of manganese or rhenium. If selected from group 8 of the periodic table, the metal may be one or more of iron, ruthenium and osmium. The group 8 metal is desirably iron. The iron oxide may have a formula selected from the group consisting of FeO, Fe₂O₃ and Fe₃O₄, and is most preferably γ-Fe₂O₃.

If selected from group 9 of the periodic table, the metal may be one or more of cobalt, rhodium and iridium. If selected from group 10 of the periodic table, the metal may be one or more of nickel, palladium and platinum. If selected from group 11 of the periodic table, the metal may be one or more of copper, silver and gold. If selected from group 10 of the periodic table, the metal may be one or more of zinc, cadmium and mercury, with zinc being preferred.

The metal may be a lanthanide.

If selected from group 14 of the periodic table, the metal may be one or more of silicon, germanium, tin or lead. If selected from group 55 of the periodic table, the metal may be one or more of arsenic, antimony or bismuth.

It will be appreciated that the fifth and sixth aspects of the present invention are suitable to produce nanoparticles comprising a core and layer, wherein one of the core and layer is a III-V semiconductor material and the other is a metal oxide material in which the metal is taken from any appropriate group of the periodic table. Thus, with regard to nanoparticles formed according to the second and fifth aspects of the present invention, the metal of the metal oxide may be taken from any one of groups 1 to 12, 14 and 15, but further, the metal may be selected from group 13 of the periodic table and therefore may be selected from the group consisting of boron, aluminium, gallium, indium and thallium.

In an embodiment of the first aspect of the invention, the nanoparticle comprises a core of indium phosphide and a shell of zinc oxide grown on the core. The nanoparticle may be formed by growing a core of indium phosphide on a II-VI semiconductor cluster, such as zinc sulfide, and then depositing a shell of zinc oxide by thermal decomposition of a zinc-containing carboxylic acid solution.

In other aspects, the invention is directed to the preparation of nanoparticulate materials incorporating a semiconductor material and metal oxide material, wherein the metal is taken from one of group 3 to 10 of the periodic table, and includes compound semiconductor particles otherwise referred to as quantum dots or nanocrystals within the size range 2-100 nm.

The semiconductor material may form the core material of the nanoparticle. In some embodiments the same or a different semiconductor material may form one or more shell layers around the nanoparticle core, subject to the proviso that the nanoparticle material also incorporates a material that is an oxide of a metal chosen from one of groups 3 to 10 of the periodic table. The semiconductor material in the nanoparticle core and/or one or more shells provided on the core may comprise ions selected from at least one of groups 2 to 16 of the periodic table.

The semiconductor material may incorporate ions from group 2 (IIA) of the periodic table, which may one or more of magnesium, calcium or strontium. The semiconductor material may incorporate ions from group 12 (IIB) of the periodic table, such as one or more of zinc, cadmium or mercury. The semiconductor material may incorporate ions from group 13 (IIIB), for example, one or more of boron, aluminium, gallium or indium. The semiconductor material may incorporate ions from group 14 (IV), such as lead and/or tin ions. By way of further example, the group 14 ions may be carbide ions.

The semiconductor material may incorporate ions from group 16 (VIB) of the periodic table, such as one or more of sulfur, selenium or telurium. There may be incorporated in the semiconductor material ions from group 15 (VB) of the periodic table, such as one or more of phosphide, arsenide or nitride. The semiconductor material may incorporate ions from the transition metal group of the periodic table and/or ions from the d-block of the periodic table.

The nanoparticle core semiconductor material may comprise:
IIA-VIB (2-16) material incorporating a first element from group 2 of the periodic table and a second element from group 16 of the periodic table and also including ternary and quaternary materials and doped materials. Suitable nanoparticle semiconductor materials include but are not restricted to MgS, MgSe, MgTe, CaS, CaSe, CaTe, SrS, SrSe, SrTe, BaS, BaSe, BaTe.
IIB-VIB (12-16) material incorporating a first element from group 12 of the periodic table and a second element from group 16 of the periodic table and also including ternary and quaternary materials and doped materials. Suitable nanoparticle semiconductor materials include but are not restricted to ZnS, ZnSe, ZnTe, CdS, CdSe, CdTe, HgS, HgSe, HgTe.
II-V material incorporating a first element from group 12 of the periodic table and a second element from group 15 of the periodic table and also including ternary and quaternary materials and doped materials. Suitable nanoparticle semiconductor materials include but are not restricted to Zn₃P₂, Zn₃As₂, Cd₃P₂, Cd₃As₂, Cd₃N₂, Zn₃N₂.
III-V material incorporating a first element from group 13 of the periodic table and a second element from group 15 of the periodic table and also including ternary and quaternary materials and doped materials. Suitable nanoparticle semiconductor materials include but are not restricted to BP, AlP, AlAs, AlSb; GaN, GaP, GaAs, GaSb; InN, InP, InAs, InSb, AlN, BN.
III-IV material incorporating a first element from group 13 of the periodic table and a second element from group 14 of the periodic table and also including ternary and quaternary materials and doped materials. Suitable nanoparticle semiconductor materials include but are not restricted to B₄C, Al₄C₃, Ga₄C.
III-VI material incorporating a first element from group 13 of the periodic table and a second element from group 16 of the periodic table and also including ternary and quaternary materials. Suitable nanoparticle semiconductor materials include but are not restricted to Al₂S₃, Al₂Se₃, Al₂Te₃, Ga₂S₃, Ga₂Se₃,GeTe; In₂S₃, In₂Se₃, Ga₂Te₃, In₂Te₃, InTe.
IV-VI material incorporating a first element from group 14 of the periodic table and a second element from group 16 of the periodic table, and also including ternary and quaternary materials and doped materials. Suitable nanoparticle semiconductor materials include but are not restricted to PbS, PbSe, PbTe, SnS, SnSe, SnTe.
Nanoparticle semiconductor material incorporating a first element from any group in the transition metal of the periodic table, and a second element from any group of the d-block elements of the periodic table and also including ternary and quaternary materials and doped materials. Suitable nanoparticle semiconductor materials include but are not restricted to NiS, CrS, CuInS₂.

The material used on any shell or subsequent numbers of shells in most cases will be of a similar lattice type material to the immediate inner layer upon which the next layer is being grown, i.e., have close lattice match to the immediate inner material so that it may be epitaxially grown, but is not necessarily restricted to materials of this compatibility. A buffer layer comprising a third material may be grown on the outside of the core, between the core and the shell if, for example the two materials, core and shell, are incompatible or not sufficiently compatible to facilitate acceptable growth of the second material on the core. The third material may be a semiconductor material incorporating ions from at least one of groups 2 to 16 of the periodic table.

The nanoparticle shell or buffer layer semiconductor material may comprise:
IIA-VIB (2-16) material incorporating a first element from group 2 of the periodic table and a second element from group 16 of the periodic table and also including ternary and quaternary materials and doped materials. Suitable nanoparticle semiconductor materials include but are not restricted to MgS, MgSe, MgTe, CaS, CaSe, CaTe, SrS, SrSe, SrTe.
IIB-VIB (12-16) material incorporating of a first element from group 12 of the periodic table and a second element from group 16 of the periodic table and also including ternary and quaternary materials and doped materials. Suitable nanoparticle semiconductor materials include but are not restricted to ZnS, ZnSe, ZnTe, CdS, CdSe, CdTe, HgS, HgSe, HgTe.
II-V material incorporating a first element from group 12 of the periodic table and a second element from group 15 of the periodic table and also including ternary and quaternary materials and doped materials. Suitable nanoparticle semiconductor materials include but are not restricted to Zn₃P₂, Zn₃As₂, Cd₃P₂, Cd₃As₂, Cd₃N₂, Zn₃N₂.
III-V material incorporating a first element from group 13 of the periodic table and a second element from group 15 of the periodic table and also including ternary and quaternary materials and doped materials. Suitable nanoparticle semiconductor materials include but are not restricted to BP, AlP, AlAs, AlSb; GaN, GaP, GaAs, GaSb; InN, InP, InAs, InSb, MN, BN.
III-IV material incorporating a first element from group 13 of the periodic table and a second element from group 14 of the periodic table and also including ternary and quaternary materials and doped materials. Suitable nanoparticle semiconductor materials include but are not restricted to B₄C, Al₄C₃, Ga₄C.
III-VI material incorporating a first element from group 13 of the periodic table and a second element from group 16 of the periodic table and also including ternary and quaternary materials. Suitable nanoparticle semiconductor materials include but are not restricted to Al₂S₃, Al₂Se₃, Al₂Te₃, Ga₂S₃, Ga₂Se₃; In₂S₃, In₂Se₃, Ga₂Te₃, In₂Te₃.
IV-VI material incorporating a first element from group 14 of the periodic table and a second element from group 16 of the periodic table and also including ternary and quaternary materials and doped materials. Suitable nanoparticle semiconductor materials include but are not restricted to PbS, PbSe, PbTe, SnS, SnSe, SnTe.
Nanoparticle material incorporating a first element from any group in the transition metal of the periodic table, and a second element from any group of the d-block elements of the periodic table and also including ternary and quaternary materials and doped materials. Suitable nanoparticle semiconductor materials include but are not restricted to NiS, CrS, CuInS₂.

The metal oxide material(s) in the nanoparticle core and/or any number of shell layers may be an oxide of any metal taken from groups 3 to 10 of the periodic table.

The metal may be selected from any one of groups 5 to 10 of the periodic table. More preferably the metal is selected from any one of groups 6 to 9 of the periodic table, and still more preferably the metal is selected from any one of groups 7 to 9 of the periodic table. It is particularly preferred that the metal is selected from group 8 of the periodic table. The group 8 metal may be selected from the group consisting of iron, ruthenium and osmium, and is most preferably iron. The iron oxide may have a formula selected from the group consisting of FeO, Fe₂O₃ and Fe₃O₄, and is most preferably maghemite or γ-Fe₂O₃.

The metal oxide may include but is not restricted to oxides of the following transition metals: Scandium (Sc), Yttrium (Y), Titanium (Ti), Zirconium (Zr), Hafnium (Hf), Vanadium (V), Niobium (Nb), Tantalum (Ta), Chromium (Cr), Molybdenum (Mo), Tungsten (W), Manganese (Mn), Rhenium (Re), Iron (Fe), Ruthenium (Ru), Osmium (Os), Cobalt (Co), Rhodium (Rh), Iridium (Ir), Nickel (Ni), Palladium (Pd), and Platinum (Pt).

In preferred embodiments of the first and third aspects of the present invention, the nanoparticle comprises a core of indium phosphide and a shell of iron oxide, preferably γ-Fe₂O₃, grown on the core. The nanoparticle is preferably formed by growing a core of indium phosphide on a II-VI semiconductor cluster, such as zinc sulfide, and then depositing a shell of iron oxide derived from iron cupferron, preferably Fe₂(cup)₃.

Nanoparticles within the first and third aspects of the present invention and formed using the methods described herein include not only binary-phase materials incorporating two types of ions, but also ternary- and quaternary-phase nanoparticles incorporating, respectively, three or four types of ions. It will be appreciated that ternary phase nanoparticles have three component materials and quaternary phase nanoparticles have four component materials.

Doped nanoparticles are nanoparticles of the above type which further incorporate a dopant comprising one or more main group or rare earth elements, most often a transition metal or rare earth element, such as, but not limited to, Mn⁺ or Cu²⁺.

Nanoparticle Shape

The shape of the nanoparticle is not restricted to a sphere and may take any desirable shape, for example, a rod, sphere, disk, tetrapod or star. The control of the shape of the nanoparticle may be achieved in the reaction particle-growth process by the addition of a compound that will preferentially bind to a specific lattice plane of the growing particle and subsequently inhibit or slow particle growth in a specific direction. Without restriction, examples of compounds that may be added include: phosphonic acids (n-tetradecylphosphonic acid, hexylphoshonic acid, 1-decanesulfonic acid, 12-hydroxydodecanoic acid, n-octadecylphosphonic acid).

The precursors used for the semiconductor material(s) that may form the nanoparticle core and/or any outer shell layers or subsequent shell layers may be provided from separate sources or from a single source.

M Ion Source

For a compound semiconductor nanoparticle material having the formula (ME)ₙLₘ (where M=first element, E=second element, L=ligand (e.g., coordinating organic layer/capping agent), and n and m represent the appropriate stoichiometric amounts of components E and L), a source (i.e., precursor) for element M is added to the reaction and may be any M-containing species having the ability to provide the growing particles with a source of M ions. The precursor may comprise, but is not restricted to, an organometallic compound, an inorganic salt, a coordination compound or the element.

With respect to element M, examples for II-VI, III-V, III-VI and IV-V semiconductor materials include but are not restricted to:
Organometallic compounds such as but not restricted to a MR₂ where M=Mg R=alky or aryl group (Mg^{t}Bu₂); MR₂ where M=Zn, Cd, Te; R=alky or aryl group (Me₂Zn, Et₂Zn Me₂Cd, Et₂Cd); MR₃ Where M=Ga, In, Al, B; R=alky or aryl group [AlR₃, GaR₃, InR₃ (R=Me, Et, ⁱPr)].
Coordination compounds such as a carbonate but not restricted to a MCO₃ M=Ca, Sr, Ba, [magnesium carbonate hydroxide (MgCO₃)₄.Mg(OH)₂]; M(CO₃)₂ M=Zn, Cd; MCO₃ M=Pb: acetate: M(CH₃CO₂)₂ M=Mg, Ca, Sr, Ba; Zn, Cd, Hg; M(CH₃C)₃ M=B, Al, Ga, In: a β-diketonate or derivative thereof, such as acetylacetonate (2,4-pentanedionate) [CH₃COOCH═C(O—)CH₃]₂ M=Mg, Ca, Sr, Ba, Zn, Cd, Hg; [CH₃COOCH═C(O—)CH₃]₂ M=B, Al, Ga, In. Oxalate SrC₂O₄, CaC₂O₄, BaC₂O₄, SnC₂O₄.
Inorganic salts such as but not restricted to an oxide (e.g., SrO, ZnO, CdO, In₂O₃, Ga₂O₃, SnO₂, PbO₂) or a nitrate (e.g., Mg(NO₃)₂, Ca(NO₃)₂, Sr(NO₃)₂, Ba(NO₃)₂, Cd(NO₃)₂, Zn(NO₃)₂, Hg(NO₃)₂, Al(NO₃)₃, In(NO₃)₃, Ga(NO₃)₃, Sn(NO₃)₄, Pb(NO₃)₂)
Elemental sources such as but not restricted to Mg, Ca, Sr, Ba, Zn, Cd, Hg, B, Al, Ga, In, Sn, Pb.

E Ion Source

For a compound semiconductor nanoparticle material having the formula (ME)ₙLₘ (where M=first element, E=second element, L=ligand (e.g., coordinating organic layer/capping agent), and n and m represent the appropriate stoichiometric amounts of components E and L), a source (i.e., precursor) for element E is added to the reaction and may be any E-containing species that has the ability to provide the growing particles with a source of E ions. The precursor may comprise, but is not restricted to, an organometallic compound, an inorganic salt, a coordination compound or the element.

With respect to element E, examples for an II-VI, III-V, III-VI or IV-V semiconductor materials include but are not restricted to:
Organometallic compounds such as but not restricted to a NR₃, PR₃, AsR₃, SbR₃ (R=Me, Et, ^{t}Bu, ⁱBu, Prⁱ, Ph etc.); NHR₂, PHR₂, AsHR₂, SbHR₂ (R=Me, Et, ^{t}Bu, ⁱBu, Prⁱ, Ph etc.); NH₂R, PH₂R, AsH₂R, SbH₂R₃ (R=Me, Et, ^{t}Bu, ⁱBu, Prⁱ, Ph etc.); PH₃, AsH₃; M(NMe)₃ M=P, Sb, As; dimethyldrazine (Me₂NNH₂); ethylazide (Et-NNN); hydrazine (H₂NNH₂); Me₃SiN₃.
MR₂ (M=S, Se Te; R=Me, Et, ^{t}Bu, ⁱBu, and the like.); HMR (M=S, Se Te; R=Me, Et, ^{t}Bu, ⁱBu, ⁱPr, Ph, and the like); thiourea S═C(NH₂)₂; Se═C(NH₂)₂.
Sn(CH₄)₄, Sn(C₄H₉), Sn(CH₃)₂(OOCH₃)₂.
Coordination compounds such as but not restricted to a carbonate, MCO₃ M=P, bismuth subcarbonate (BiO)₂CO₃; M(CO₃)₂; acetate M(CH₃CO)₂ M=S, Se, Te: M(CH₃C)₃ M=Sn, Pb: a β-diketonate or derivative thereof, such as acetylacetonate (2,4-pentanedionate) [CH₃COOCH═C(O—)CH₃]₃M M=Bi; [CH₃COOCH═C(O—)CH₃]₂M M=S, Se, Te: [CH₃COOCH═C(O—)CH₃]₂M M=Sn, Pb: thiourea, selenourea (H₂NC(═Se)NH₂
Inorganic salts such as but not restricted to the oxides P₂O₃, As₂O₃, Sb₂O₃, Sb₂O₄, Sb₂O₅, Bi₂O₃, SO₂, SeO₂, TeO₂, Sn₂O, PbO, PbO₂; Nitrates Bi(NO₃)₃, Sn(NO₃)₄, Pb(NO₃)₂
Elemental sources such as but not restricted to Sn, Ge, N, P, As, Sb, Bi, S, Se, Te, Sn, Pb.

Combined ME Ion Sources—ME Single Source Precursors

For a compound semiconductor nanoparticle comprising elements M and E, a source for elements M and E may be in the from of a single-source precursor, whereby the precursor to be used contains both M and E within a single molecule.

This precursor may be an organometallic compound, an inorganic salt or a coordination compound, (MₐE_{b})L_{c} where M and E are the elements required within the nanoparticles, L is the capping ligand, and a, b and c are numbers representing the appropriate stroichiometry of M, E and L.

Examples for a II-VI semiconductor where M=II and E=VI element may be but are not restricted to bis(dialkyldithio-carbamato)M,(II) complexes or related Se and Te compounds of the formula M(S₂CNR₂)₂ M=Zn, Cd, Hg; S═S, Se, O, Te and R=alkyl or ary groups; CdS Cd[SSiMe₃]₂, Cd(SCNHNH₂)₂Cl₂, Cd(SOCR)₂.py; CdSe [Cd(SePh)₂]₂.

For III-V semiconductors the precursors may be but are not restricted to:
for GaN: [(Me)₂GaN(H)^{t}Bu]₂ [H₂GaNH₂]₃;
for GaP: [Ph₂GaP(SiMe₃)₃Ga(Ph)₂Cl][Et₂GaP(SiMe₃)₂]₂, [Et₂GaPEt₂]₃, [^{t}Bu₂GaPH₂]₃ [Me₂GaP(ⁱPr)₂]₃ [^{t}BuGaPAr′]₂, [^{t}Bu₂GaP(H)C₅H₉]₂;
for GaAs: Ga(As^{t}Bu₂)₃ [Et₂GaAs(SiMe₃)₂]₂, [^{t}Bu₂GaAs(SiMe₃)₂]₂;
for GaSb: [Et₂GaSb(SiMe₃)₂]₂;
for InP: [(Me₃SiCH₂)₂InP(SiMe₃)₂]₂ [R₂InP(SiMe₃)₂]₂, [Me₂InP^{t}Bu₂]₂;
for InSb: [Me₂InSb^{t}Bu₂]₃ [Et₂InSb(SiMe₃)₂]₃, [Me₂InNEt₂]_{2,} [Et₂AlAs^{t}Bu₂]₂;
for AlSb: [^{t}Bu₂AlSb(SiMe₃)₂]₂;
for GaAs: [ⁿBu₂GaAs^{t}Bu₂]₂ [Me₂Ga₂As^{t}Bu₂]₂ [Et₂GaAs^{t}Bu₂]₂.

For II-V semiconductors the precursors may be but are not restricted to, for Cd₃P₂, [MeCdP^{t}Bu₂]₃ Cd[P(SiPh₃)₂]₂; Zn₃P₂ Zn[P(SiPh₃)₂]₂.

For IV-VI semiconductors the precursors may be but are not restricted to:
for PbS: lead (II) dithiocarbamates;
for PbSe: lead (II)selenocarbamates.

Metal-Oxide Outer Layer

For the growth of the metal oxide core and/or shell layer(s), a source for the metal element is added to the reaction and may comprise any metal-containing species that has the ability to provide the growing particles with a source of the appropriate metal ions. The precursor may also be the source of the oxygen atoms if they are present within the precursor or the oxygen source may be from a separate oxygen-containing precursor including oxygen. The precursor may comprise but is not restricted to an organometallic compound, an inorganic salt, a coordination compound or the element itself.

The metal oxide precursor may be but is not restricted to the following:

Oxides of Group 1 (IA)

Lithium (Li), Sodium (Na), Potassium (K)

Oxides of Group 2 (IIA)

Beryllium (Be), Magnesium (Mg), Calcium (Ca), Strontium (Sr) Barium (Ba)

Oxides of the Transition Elements, Groups 3-12 (IIIB, IVB, VB, VIB, VIIB, VIIIB, IB, IIB)

Scandium (Sc), Yttrium (Y), Titanium (Ti), Zirconium (Zr), Hafnium (Hf), Vanadium (V), Niobium (Nb), Tantalum (Ta), Chromium (Cr), Molybdenum (Mo), Tungsten (W), Manganese (Mn), Rhenium (Re), Iron (Fe), Ruthenium (Ru), Osmium (Os), Cobalt (Co), Rhodium (Rh), Iridium (Ir), Nickel (Ni), Palladium (Pd), Platinum (Pt), Copper (Cu), Silver (Ag), Gold (Au), Zinc (Zn), Cadmium (Cd) and Mercury (Hg). For example, the metal oxide precursor may be but is not restricted to oxides of the following transition metals: Scandium (Sc), Yttrium (Y), Titanium (Ti), Zirconium (Zr), Hafnium (Hf), Vanadium (V), Niobium (Nb), Tantalum (Ta), Chromium (Cr), Molybdenum (Mo), Tungsten (W), Manganese (Mn), Rhenium (Re), Iron (Fe), Ruthenium (Ru), Osmium (Os), Cobalt (Co), Rhodium (Rh), Iridium (Ir), Nickel (Ni), Palladium (Pd), and Platinum (Pt).

Oxides of the Lanthanides

Lanthanum (La), Cerium (Ce), Praseodymium (Pr), Neodymium (Nd), Samarium (Sm), Europium (Eu), Gadolinium (Gd), Terbium (Tb), Dysprosium (Dy), Holmium (Ho), Erbium (Er), Thulium™, Ytterbium (Yb), Lutetium (Lu).

Oxides of Group 13(IIIA)—For Use in the Fifth and Sixth Aspects of the Present Invention.

Boron (B), Aluminium (Al), Gallium (Ga), Indium (In), Thallium (Tl)

Oxides of Group 14 (IVA)

Silicon (Si), Germanium (Ge), Tin (Sn), Lead (Pb)

Oxides of Group 15 (VA)

Arsenic (As), Antimony (Sb), Bismuth (Bi)

In a preferred method for providing a shell layer of metal oxide, a molecular complex containing both the metal ions and oxide ions to be incorporated into the metal oxide layer may be used. The complex may be added to the nanoparticle cores (e.g., InP or CdSe) in a single portion or a plurality (e.g., 2, 3, 4 or 5) of portions sufficient to provide the required amount of metal ions and oxide ions.

A preferred oxide ion containing anionic complex that may be used in combination with a suitable metal cation is N-nitrosophenylhydroxylamine (cupferron). This anionic complex is particularly suitable for use with ferric ions. Accordingly, a particularly preferred complex used to provide an iron oxide shell on a semiconductor core nanoparticle is ferric cupferron.

It may be advantageous to heat a solution containing the nanoparticle cores prior to addition of the molecular complex. Suitable temperatures may be in the range around 150° C. to around 300° C., more preferably around 180° C. to around 270° C., still more preferably around 200° C. to around 250° C. and most preferably around 220° C. to around 230° C.

Following addition of the molecular complex (when a single portion is used) or addition of the final portion of the molecular complex (when two or more portions are used) it may be desirable to cool the nanoparticle solution to a lower temperature, for example, around 160° C. to around 200° C., more preferably around 180° C., depending in part upon the temperature of the nanoparticle solution prior to and during addition of the molecular complex.

Following cooling, the nanoparticle solution may then be maintained at the cooler temperature over a period of time to allow the nanoparticles to anneal. Preferred annealing periods are in the range around 1 hour to around 72 hours, more preferably around 12 hours to around 48 hours, and most preferably around 20 to 30 hours.

Following annealing, it may be appropriate to further cool the nanoparticle solution to a lower temperature (e.g., around 30° C. to around 100° C., more preferably around 50° C. to around 80° C., more preferably around 70° C.) to restrict further nanoparticle growth and facilitate isolation of the final metal oxide coated nanoparticles.

A further preferred method for providing a shell layer of metal oxide involves decomposition of a metal carboxylate in the presence of a long chain (e.g., C₁₆-C₂₀) alcohol to yield the metal oxide, which may be deposited on the nanoparticle core, and an ester as the bi-product. In this method, the metal carboxylate is preferably added to a solution containing the nanoparticle cores, which then heated to a first elevated temperature before addition of a solution containing a predetermined amount of the long chain alcohol. The mixture is then preferably maintained at the first temperature for a predetermined period of time. The temperature of the mixture may then be further increased to a second temperature and maintained at that increased temperature for a further period of time before cooling to around room temperature at which point the metal oxide coated nanoparticles may be isolated.

The first elevated temperature is preferably in the range around 150° C. to around 250° C., more preferably around 160° C. to around 220° C., and most preferably around 180° C. Subject to the proviso that the second temperature is higher than the first temperature, the second temperature is preferably in the range around 180° C. to around 300° C., more preferably around 200° C. to around 250° C., and most preferably around 230° C.

The alcoholic solution is preferably added slowly to the carboxylate solution, for example, the alcoholic solution may be added over a period of at least 2 to 3 minutes, if not longer, such as 5 to 10 minutes or even longer.

The temperature of the reaction mixture may be maintained at the first temperature for at least around 5 to 10 minutes and more preferably longer, such as at least around 20 to 30 minutes or even longer. After raising the temperature of the reaction mixture to the second temperature it is preferred that the mixture is maintained at this increased temperature for at least around 1 to 2 minutes and more preferably longer, for example at least around 4 to 5 minutes or still longer.

Embodiments of the present invention are illustrated with reference to the following non-limiting examples.

### Examples

All syntheses and manipulations were carried out under a dry oxygen-free argon or nitrogen atmosphere using standard Schlenk or glove box techniques unless other wise stated. All solvents were distilled from appropriate drying agents prior to use (Na/K-benzophenone for THF, Et₂O, toluene, hexanes and pentane).

UV-vis absorption spectra were measured on a Heλiosβ Thermospectronic. Photoluminescence (PL) spectra were measured with a Fluorolog-3 (FL3-22) photospectrometer and using Ocean Optics instruments. Powder X-Ray diffraction (PXRD) measurements were preformed on a Bruker AXS D8 diffractometer using monochromated Cu-K₆₀ radiation.

### Example 1

### Preparation of InP/ZnO Core/Shell Nanoparticles (Red)

InP core particles were made as follows: 200 ml di-n-butylsebacate ester and 10 g myristic acid at 60° C. were placed in a round-bottomed three neck flask and purged with N₂ this was followed by the addition of 0.94 g of the ZnS cluster [HNEt₃]₄[Zn₁₀S₄(SPh)₁₆]. The reaction was then heated to 100° C. for 30 mins followed by the addition of 12 ml of 0.25M [In₂(Ac)₃(MA)₃], dissolved in di-n-butylsebacate ester, over a period of 15 mins using an electronic syringe pump at a rate of 48 ml/hr, this was followed by the addition of 12 ml 0.25M (TMS)₃P at the same addition rate.

Once additions were complete the temperature of the reaction was increased to 180° C. To grow the particles up to the required size and thus the required emission in the red, further addition of solutions of [In₂(Ac)₃(MA)₃] and (TMS)₃P were made as followed:—16 ml [In₂(Ac)₃(MA)₃] followed by 16 ml (TMS)₃P were added followed by a temperature increase to 200° C. then further additions of 10 ml of [In₂(Ac)₃(MA)₃], the temperature was then left at 200° C. for 1 hr and then lowered to 160° C. and the reaction allowed to anneal for 3 days. Then the particles were isolated using acetonitrile, centrifuged and collected. The InP quantum dots had an emission peak at 550 nm.

The formation of a ZnO shell is based on the decomposition product of a suitable metal carboxylic acid with a long chain alcohol yielding an ester as the bi-product. InP core dots 165.8 mg prepared as described above were dissolved in 10 ml of di-n-butylsebacate ester. This was then added to a 3 neck round-bottom flask containing zinc acetate and myristic acid and the flask was then degassed and purged with N₂ several times. In a separate flask a solution of 1-octadecanol (2.575 g, 9.522 mmol) and ester 5 ml of di-n-butylsebacate ester was made up at 80° C.

The reaction solution containing the dots was then heated to 180° C. at which temperature the alcohol solution was slowly added over a period of 5-10 minutes. The temperature of the reaction was then maintained for 30 minutes followed increasing the temperature to 230° C. and maintained at this temperature for 5 minutes before cooling to room temperature.

The sample was isolated by the addition of excess acetonitrile, centrifuging the resulting wet solid pellet was further washed with acetonitrile and centrifuging for a second time. The resulting pellet was dissolved with chloroform and filtered to remove any remaining insoluble material.

### Example 2

### Preparation of InP/ZnS/ZnO Core/Shell/Shell Nanoparticles

InP core particles were made as follows: 200 ml di-n-butylsebacate ester and 10 g myristic acid at 60° C. were placed in a round-bottomed three neck flask and purged with N₂ this was followed by the addition of 0.94 g of the ZnS cluster [HNEt₃]₄[Zn₁₀S₄(SPh)₁₆]. The reaction mixture was then heated to 100° C. for 30 mins followed by the addition of 12 ml of 0.25M [In₂(Ac)₃(MA)₃], dissolved in di-n-butylsebacate ester, over a period of 15 mins using an electronic syringe pump at a rate of 48 ml/hr, this was followed by the addition of 12 ml 0.25M (TMS)₃P at the same addition rate.

Once additions were complete the temperature of the reaction was increased to 180° C. To grow the particles up to the required size and thus the required emission in the red, further addition of solutions of [In₂(Ac)₃(MA)₃] and (TMS)₃P were made as followed:—16 ml [In₂(Ac)₃(MA)₃] followed by 16 ml (TMS)₃P were added followed by a temperature increase to 200° C. then further additions of 10 ml of [In₂(Ac)₃(MA)₃], the temperature was then left at 200° C. for 1 hr and then lowered to 160° C. and the reaction allowed to anneal for 3 days. Then the particles were isolated using acetonitrile, centrifuged and collected. The InP quantum dots had an emission peak at 550 nm.

Two methods using different S sources (Method 1, (TMS)₂S; Method 2, octanethiol) were employed to form a buffer layer of ZnS on the InP core nanoparticles prior to addition of the ZnO outer shell. These are described in turn.

Method 1

3.13 g (13.7 mmol) of myristic acid and 6.75 ml of di-n-butyl sebacate ester were degassed. 300 mg of the HF etched InP dots and 1.68 g (9.15 mmol) of anhydrous zinc acetate was added at room temperature. The solution was slowly heated to 180° C. 9.2 ml (2.3 mmol) of 0.25M (TMS)₂S was added dropwise and after completion the mixture was stirred for 30 minutes.

Method 2

3.13 g of myristic acid and 6.75 ml of di-n-butyl sebacate ester were degassed. 300 mg of the HF etched InP dots and 1.68 g anhydrous zinc acetate was added at room temperature. The solution was slowly heated to 120° C. 0.4 ml (2.3 mmol) octanethiol was added in one portion and the temperature increased to 180° C. where it was kept for 30 minutes.

The formation of a ZnO shell is based on the decomposition product of a suitable metal carboxylic acid with a long-chain alcohol yielding an ester as the bi-product. InP core dots (165.8 mg) prepared as described above were dissolved in 10 ml of di-n-butylsebacate ester. This was then added to a 3-neck round-bottom flask containing zinc acetate and myristic acid, and the flask was degassed and purged with N₂ several times. In a separate flask a solution of 1-octadecanol (2.575 g, 9.522 mmol) and ester 5 ml of di-n-butylsebacate ester was made up at 80° C.

The reaction solution containing the dots were then heated to 180° C. at which temperature the alcohol solution was slowly added over a period of 5-10 minutes. The temperature of the reaction was then maintained for 30 minutes followed increasing the temperature to 230° C. and maintained at this temperature for 5 minutes before cooling to room temperature.

The sample was isolated by the addition of excess acetonitrile, centrifuging the resulting wet solid pellet was further washed with acetonitrile and centrifuging for a second time. The resulting pellet was dissolved with chloroform and filtered to remove any remaining insoluble material.

### Example 3

### Preparation and Properties of InP/Fe₂O₃ Core/Shell Nanoparticles

InP core particles were made as follows: 200 ml di-n-butylsebacate ester and 10 g myristic acid at 60° C. were placed in a round-bottomed three-neck flask and purged with N₂ this was followed by the addition of 0.94 g of the ZnS cluster [HNEt₃]₄[Zn₁₀S₄(SPh)₁₆]. The reaction was then heated to 100° C. for 30 minutes followed by the addition of 12 ml of 0.25M solution of [In₂(Ac)₃(MA)₃] dissolved in di-n-butylsebacate ester over a period of 15 minutes using an electronic syringe pump at a rate of 48 ml/hr, this was followed by the addition of 12 ml of a 0.25M solution of (TMS)₃P dissolved in di-n-butylsebacate ester at the same addition rate.

Once additions were complete the temperature of the reaction was increased to 180° C. To grow the particles up to the required size and thus the required emission in the red, further addition of [In₂(Ac)₃(MA)₃] and (TMS)₃P were made as follows: 16 ml [In₂(Ac)₃(MA)₃] followed by 16 ml (TMS)₃P were added followed by a temperature increase to 200° C. then further additions of 10 ml of [In₂(Ac)₃(MA)₃], the temperature was then left at 200° C. for 1 hr and then lowered to 160° C. and the reaction allowed to anneal for 3 days. The particles were isolated using acetonitrile, centrifuged and collected. The InP quantum dots had an emission at 550 nm.

The InP nanoparticles were precipitated with methanol and isolated as a pellet by centrifugation. The supernate was discarded and 1.0 g of the InP pellet were placed in a 125 mL round-bottom flask containing 50 g hexadecylamine that had previously been dried and degassed under vacuum at 120° C.

The solution temperature was raised to 230° C. and 3.30 mL of a 0.0286 M ferric cupferron solution in octylamine was added dropwise over a 10-minute period. The solution was left stirring for an additional 20 minutes before an aliquot was taken and a second 3.30 mL portion of ferric cupferron solution was added dropwise over a 10 minute period. The solution was stirred for 20 minutes and an aliquot was taken. A third and final 3.30 mL portion of ferric cupferron solution was added dropwise over a 10 minute period.

After the final addition, the reaction was stirred for an additional 20 minutes, cooled to 180° C. and left stirring at 180° C. for 24 hr before cooling to 70° C. Methanol was added to precipitate the particles. The precipitate was isolated as a pellet by centrifugation and the supernate was discarded.

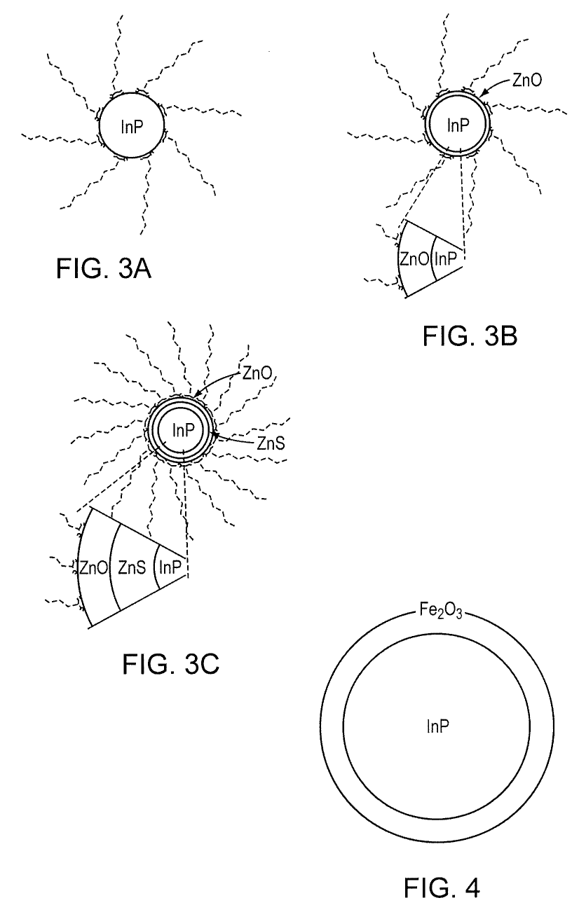

The PL emission intensity for that of the core/shell particles was about 200 times more intense than that of the core particles prior to the addition of the Fe₂O₃ layer. A schematic representation of InP/Fe₂O₃ core/shell nanoparticles is shown in FIG. 3.

### Example 4

Red-emitting InP nanoparticle cores were produced as described in Example 1.

A method similar to that described in Example 1 was then used to deposit a layer of In₂O₃ on the InP cores: 30 ml of the InP reaction solution was removed and then heated under Ar to 180° C. Slowly 3 ml of octanol was added and then left for 30 minutes before cooling to room temperature. While the applicants do not wish to be bound by any particular theory, it is believed that excess In(MA)₃ in the InP core reaction solution reacted with the octanol to deposit an In₂O₃ shell on the InP cores.

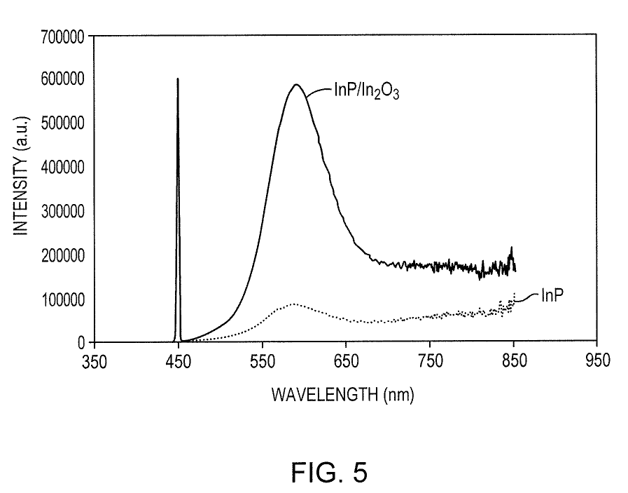

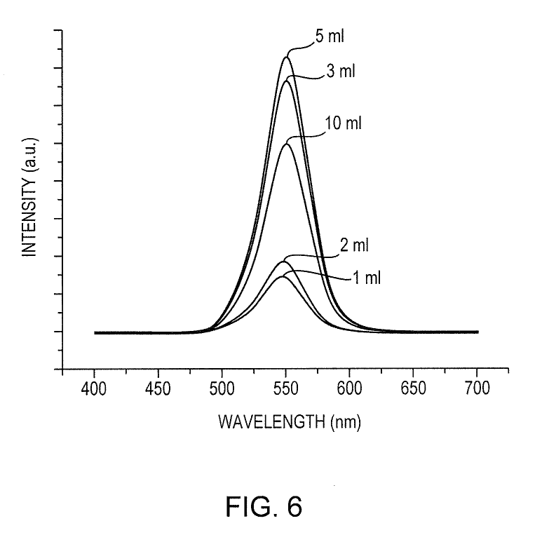

It was observed that the quantum yield of the In₂O₃ core/shell nanoparticles was 6 times greater than the quantum yield of the unshelled InP cores (see FIG. 5).

It is postulated that a shell of In₂O₃ may act as a buffer layer between InP cores and outer layers of ZnS and ZnO in nanoparticles produced according to Example 2 above. On the basis of the improvement in quantum yield observed when InP cores were coated with In₂O₃, the addition of a further buffer layer of In₂O₃ (in addition to a buffer layer of ZnS) may improve both the final quantum yield and/or stability of the InP/In₂O₃/ZnS/ZnO nanoparticle material as compared to the InP/ZnS/ZnO produced in Example 2.

### Example 5

### Synthesis of CdSe/Fe₂O₃ (with Green Emission)

In a typical synthesis 100 g HDA (hexadecylamine) was degassed at 120° C. for an hour. The flask was then purged with nitrogen and 1.25 g of [Et₃NH]₄[Cd₁₀Se₄(SPh)₁₆] was added in one portion as a solid at 100° C. The solution was slowly heated to 260° C. and kept at this temperature for about 1 hour. The solution was cooled to 150° C. and a further 0.25 g [Et₃NH]₄[Cd₁₀Se₄(SPh)₁₆] was added. The solution was reheated to 260° C. for a further hour or until the maximum emission peak reached 550 nm. The CdSe nanoparticles were collected by cooling the reaction solution, precipitating with excess methanol centrifuging and drying with a nitrogen flow.

A dilute solution of FeCup₃ in octylamine was made, 30 ml octylamine, 0.248 g FeCup₃ was dissolved to give a 0.018M solution. In a separate flask, 75 g HDA was degassed at 120° C., then cooled to 100° C. and 0.3 g of the 550 nm CdSe particles added. The temperature of the reaction was raised to 230° C. and the FeCup₃/octylamine solution was added dropwise in 5 separate portions of 1 ml, 1 ml, 1 ml, 2 ml and 5 ml making in total 10 ml of added solution. The reaction was left to stir for 5 minutes in-between each portion.

After the complete addition of FeCup₃ reaction was cooled to 180° C. and left to anneal for up to 3 hours, then cooled to room temperature and isolated by precipitating with methanol, then centrifuging and dried with a nitrogen flow.

Elemental analysis gave C=24.42, H=3.93, N=1.32, Cd=42.46, Fe=2.61.

### Example 6

### Preparation of CdSe/Fe₂O₃ Core/Shell Nanoparticles (with Red Emission)

A 25 g portion of hexadecylamine (HDA) was placed in a three-neck round-bottomed flask and dried and degassed by heating to 120° C. under a dynamic vacuum for >1 hour. The solution was cooled to 60° C., the reaction flask was filled with nitrogen and the following reagents were loaded into the flask using standard airless techniques: 0.10 g [HNEt₃]₄[Cd₁₀Se₄(SPh)₁₆], 2 mL of a premixed precursor solution (a solution of 0.25M Me₂Cd and 0.25 M elemental selenium dissolved in trioctylphosphine). The temperature was increased to 120° C. and allowed to stir for 2 hours. At this point a programmed temperature ramp from 120° C. to 200° C. at a rate of ˜0.2° C./min was initiated. Simultaneously, an additional 4 mL of the premixed precursor solution was added dropwise at a rate of ˜0.05 mL/min.

Particle growth was stopped when the PL emission maximum had reached the required emission (λₘₐₓ=585 nm) by cooling to 60° C. followed by the addition of an excess of dry methanol to precipitate the particles from solution. The precipitate was isolated by centrifugation, the pellet was retained and the supernate was discarded.

A 125 mg portion of the CdSe pellet was placed in a 125 mL round-bottom flask containing 25 g octadecylamine that had previously been dried and degassed under vacuum at 120° C. The solution temperature was raised to 220° C. and 2.5 mL of a 0.0286 M ferric cupferron solution in octylamine was added dropwise over a 10 minute period. The solution was left stirring for an additional 20 minutes before a second 2.5 mL portion of ferric cupferron solution was added dropwise over a 10 minute period. The solution was stirred for 20 min. A third and final 2.5 mL portion of ferric cupferron solution was added dropwise over a 10 minute period.

After the final addition, the reaction was stirred for an additional 20 minutes, and the reaction was cooled to 180° C. The solution was left stirring at 180° C. for 4 hr before cooling to 70° C. and 15 mL of the reaction mixture was removed and placed in a centrifuge tube. A 45 mL portion of methanol was added to precipitate the particles. The precipitate was isolated as a pellet by centrifugation and the supernate was discarded. Portions of the pellet were redispersed in toluene.

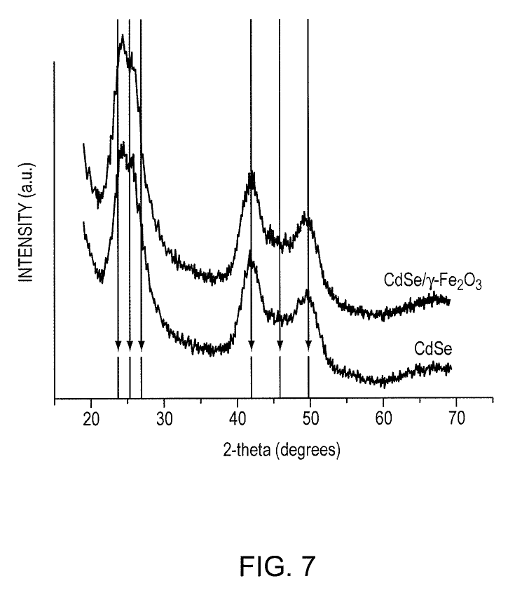

The formation of the FeCup₃ layer produces a slight red shift both in PL maximum and first absorption peak (see FIG. 7) of ˜3.5 nm, which is considerably less than the shift when either CdS or ZnS is grown epitaxially onto the particle.

FIG. 7 shows that the XRD pattern of CdSe/γ-Fe₂O₃ nanocrystals had a very similar shape to that of pure CdSe cores, however a sharpening of the three major peaks for the CdSe/γ-Fe₂O₃ may be seen. No noticeable peaks attributable to bulk γ-Fe₂O₃ are evident in the diffraction pattern.

TEM images of CdSe nanoparticles revealed average diameters of 3.7 nm. The particle size increased to 4.2 nm when shelled with Fe₂O₃. There appeared to be a slight aggregation of the nanoparticles after shelling with Fe₂O₃, however the particles still easily dissolve in organic solvents.

### Example 7

### Preparation of ZnSe/Fe₂O₃ Core/Shell Nanoparticles

A 125 mL round-bottom flask was loaded with 25 g octadecylamine and a spin-bar, the flask was attached to a schlenk line and evacuated. The solvent was dried and degassed under vacuum for 1 hr at 120° C. The flask was filled with nitrogen and the temperature increased from 120° C. to 340° C. over a 2 hr period. At this point, 4 mL of a premixed precursor solution (0.25 M diethyl zinc and 0.25 M elemental selenium dissolved in TOP) was injected into the flask. The reaction temperature plunged to 300° C. immediately following the precursor solution injection and was maintained at 300° C.

An additional 16 mL portion of premixed precursor solution was added dropwise over a 4 hour period. The temperature was lowered to 250° C. and the solution was left stirring overnight. The ZnSe nanoparticles were precipitated with hot (70° C.) n-butanol and isolated as a pellet by centrifugation.

The supernate was discarded and 125 mg of the ZnSe pellet was placed in a 125 mL round-bottom flask containing 25 g octadecylamine that had previously been dried and degassed under vacuum at 120° C. The solution temperature was raised to 220° C. and 2.5 mL of a 0.0286 M ferric cupferron solution in octylamine was added dropwise over a 10 minute period. The solution was left stirring for an additional 20 minutes before an aliquot was taken and a second 2.5 mL portion of ferric cupferron solution was added dropwise over a 10 minute period. The solution was stirred for 20 minutes a third and final 2.5 mL portion of ferric cupferron solution was added dropwise over a 10 minute period.

After the final addition, the reaction was stirred for an additional 20 minutes and the reaction was allowed to cool to 180° C. The solution was left stirring at 180° C. for 4 hr before cooling to 70° C. A 15 mL portion of the reaction mixture was removed and placed in a centrifuge tube. A 45 mL portion of methanol was added to precipitate the particles. The precipitate was isolated as a pellet by centrifugation and the supernate was discarded. Portions of the pellet were redispersed in toluene.

### Example 8

### Preparation and Properties of CdTe/Fe₂O₃ Core/Shell Nanoparticles

A 125 mL round-bottom flask was loaded with 25 g hexadecylamine and a spin-bar. The flask was attached to a schlenk line and evacuated. The solvent was dried and degassed under vacuum for 1 hr at 120° C. The flask was filled with nitrogen and the temperature increased from 120° C. to 260° C. over a 2 hr period. At this point, 4 mL of a premixed precursor solution (0.25 M dimethyl cadmium and 0.25 M elemental tellurium dissolved in TOP) was added. The reaction temperature plunged to 240° C. immediately following the precursor solution injection and was maintained at 240° C. for 5 minutes. The temperature was lowered to 50° C. by removing the flask from the mantle and exposing it to a stream of cool air. The CdTe nanoparticles were precipitated with methanol and isolated as a pellet by centrifugation.

The supernate was discarded and 125 mg of the CdTe pellet were placed in a 125 mL round-bottom flask containing 25 g hexadecylamine that had previously been dried and degassed under vacuum at 120° C. The solution temperature was raised to 220° C. and 2.5 mL of a 0.0286 M ferric cupferron solution in octylamine was added dropwise over a 10 minute period. The solution was left stirring for an additional 20 minutes a second 2.5 mL portion of ferric cupferron solution was added dropwise over a 10 minute period. The solution was stirred for 20 minutes and then a third and final 2.5 mL portion of ferric cupferron solution was added dropwise over a 10 minute period.

After the final addition, the reaction was stirred for an additional 20 minutes, and the reaction was cooled to 180° C. The solution was left stirring at 180° C. for 4 hr before cooling to 70° C. A 15 mL portion of the reaction mixture was removed and placed in a centrifuge tube. A 45 mL portion of methanol was added to precipitate the particles. The precipitate was isolated as a pellet by centrifugation and the supernate was discarded. Portions of the pellet were redispersed in toluene.

### Example 9

### Preparation and Properties of InP/In₂O₃/ZnS/ZnO Core/Shell Nanoparticles

Synthesis of InP/In₂O₃ cores

| Material | Amount | | Moles | MW | Grade |
|---|---|---|---|---|---|
| Di-n-butyl-sebacate ester | 250 | ml | 0.0744 | 314.46 | tech |
| [Et₃NH]₄[Zn₁₀S₄(SPh)₁₆] | 9.4 | g | 0.0032 | 2937.67 | |
| Myristic acid | 25 | g | 4.469 × | 228.37 | 99% |
| | | | 10⁻³ | | |
| Indium myristate (1M soln in | 40 | ml | 0.04 | 796.93 | |
| ester) | | | | | |
| Tris(trimethylsilylphosphine) | 26 | ml | 0.026 | 250.54 | |
| 1M soln in ester | | | | | |
| 1-Octanol | 53.8 | | 0.3416 | 130.23 | 99% |
| Chloroform | 50 | ml | | | anhydrous |
| Methanol | 100 | mL | | | anhydrous |
| Acetonitrile | 250 | mL | | | anhydrous |

The ester was added to a 3-neck round bottomed flask equipped with condenser, thermometer and magnetic stirrer bar then degassed under vacuum at 100° C. for two hours. Temperature decreased to 70° C. and put under nitrogen atmosphere. Cluster was added in one portion and stirred for 30 minutes. Temperature increased to 100° C. then 15 ml In(MA)₃ was added dropwise. After complete addition the reaction was stirred for 5 minutes then was followed by the dropwise addition of 15 ml (TMS)₃P. Temperature increased to 160° C. then 20 ml Im(MA)₃ was added dropwise. After complete addition the reaction was stirred for 5 minutes then was followed by the dropwise addition of 8 ml (TMS)₃P. Temperature increased to 190° C. then 5 ml In(MA)₃ was added dropwise. After complete addition the reaction was stirred for 5 minutes then was followed by the dropwise addition of 3 ml (TMS)₃P. Temperature increased to 200° C. where it was left to stir for 1 hour. Temperature decreased to 160° C. and the quantum dots left to anneal for 3 days. Temperature increased to 180° C. then the octanol was added in one portion. The reaction was left to stir for 30 minutes then cooled to room temperature. Anhydrous acetonitrile was added until the particles flocculated then the precipitate was centrifuged. The wet powder was redissolved in minimum volume of chloroform and reprecipitated with methanol. The wet powder was redissolved again in the minimum volume of chloroform then reprecipited with methanol. The dots were dissolved in chloroform then etched using a dilute solution of HF in air over a period of 3 days until maximum luminescence intensity was seen.

Shelling of InP/In₂O₃ cores with ZnS/ZnO shell

| Material | Amount | | Moles | MW | Grade |
|---|---|---|---|---|---|
| InP/In₂O₃ cores | 5.64 | | | | |
| in 50 ml ester | | | | | |
| Di-n-butyl- | 70 | ml | 0.0744 | 314.46 | Tech |
| sebacate ester | | | | | |
| Undecylenic acid | 18 | g | 0.0978 | 184.28 | 98% |
| Zinc acetate | 15 | g | 0.0818 | 183.46 | 99.99% |
| 1-Octanethiol | 9 | ml | 0.0519 | 146.29 | 98.5% |
| 1-Octanol | 12.8 | | 0.0813 | 130.23 | 99% |
| Toluene | 40 | ml | | | anhydrous |
| Acetonitrile | 180 | ml | | | anhydrous |
| Ethyl acetate | 100 | ml | | | anhydrous |

The ester, cores produced as described above and undecylenic acid were added together in a 3-neck round bottomed flask equipped with condenser, thermometer and magnetic stirrer bar then degassed under vacuum for 2 hours at 100° C. The temperature was decreased to 70° C. then the zinc acetate was added in small portions to one neck of the flask under strong nitrogen flow. Temperature increased to 100° C. then the reaction was evacuated under reduced pressure for 20 minutes then purged with nitrogen. Then evacuated/purged a further two times. Temperature increased to 120° C. then the octanethiol was added in one portion. Temperature increased to 230° C. and held for 90 minutes. Temperature decreased to 180° C. then the octanol was added in one portion and held at 180° C. for 30 minutes. Solution was then cooled to room temperature. Anhydrous acetonitrile was added until the particles flocculated then the precipitate was filtered through a celite filled sinter funnel The precipitate was washed first with hot acetonitrile (discarding the washings) then washed with hot ethylacetate (that dissolves the dots). The dots dissolved in the ethylacetate was then reprecipitated by adding acetonitrile. Finally the precipitated dots was dissolved in minimum volume of toluene and stored in an inert atmosphere. InP/In₂O₃/ZnS/ZnO core/shell nanoparticles were produced emitting at 506 nm, with a full width at half maximum (FWHM) of 55 nm and quantum yield (QY) of 50%.

The terms and expressions employed herein are used as terms and expressions of description and not of limitation, and there is no intention, in the use of such terms and expressions, of excluding any equivalents of the features shown and described or portions thereof In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A nanoparticle comprising:
a core that itself comprises a first material; and
thereover, a layer that comprises a second material,
wherein one of the first and second materials is a semiconductor material incorporating ions from group 13 and group 15 of the periodic table and the other of the first and second materials is a metal oxide material incorporating metal ions selected from any one of groups 1 to 12, 14, and 15 of the periodic table.

2-8. (canceled)

9. The nanoparticle of claim 1, wherein the metal is selected from group 8 of the periodic table.

10. The nanoparticle of claim 9, wherein the group 8 metal is iron.

11. The nanoparticle of claim 10, wherein the iron oxide has a formula selected from the group consisting of FeO, Fe₂O₃, and Fe₃O₄.

12. The nanoparticle of claim 10, wherein the iron oxide is γ-Fe₂O₃.

13-14. (canceled)

15. The nanoparticle of claim 1, wherein the metal is selected from group 11 of the periodic table.

16. The nanoparticle of claim 1, wherein the metal is selected from group 12 of the periodic table.

17. The nanoparticle of claim 1, wherein the metal is selected from group 13 of the periodic table.

18-19. (canceled)

20. The nanoparticle of claim 1, wherein the group 13 ions incorporated in the semiconductor material are selected from the group consisting of boron, aluminium, gallium, and indium.

21. The nanoparticle of claim 1, wherein the group 15 ions incorporated in the semiconductor material are selected from the group consisting of phosphide, arsenide, and nitride.

22. The nanoparticle of claim 1, further comprising a layer of a third material disposed between the nanoparticle core and the layer comprising the second material.

23. The nanoparticle of claim 22, wherein the third material is a semiconductor material incorporating ions selected from at least one of groups 2 to 16 of the periodic table.

24. The nanoparticle of claim 1, wherein the first material is the semiconductor material and the second material is the metal oxide material.

25. A method for producing a nanoparticle comprising a core that comprises a first material and, thereover, a layer that comprises a second material, wherein one of the first and second materials is a semiconductor material incorporating ions from group 13 and group 15 of the periodic table and the other of the first and second materials is a metal oxide material incorporating metal ions selected from any one of groups 1 to 12, 14 and 15 of the periodic table, the method comprising:
forming the core and forming thereover the layer comprising the second material.

26. The method of claim 25, wherein the core has a composition, formation of the core comprising (i) effecting conversion of a nanoparticle core precursor composition to the composition of the nanoparticle core, and (ii) growing the core.

27. The method of claim 26, wherein the nanoparticle core precursor composition comprises first and second core precursor species containing ions to be incorporated into the growing nanoparticle core, the first and second core precursor species being separate entities in the nanoparticle core precursor composition, the conversion being effected in the presence of a molecular cluster compound under conditions permitting seeding and growth of the nanoparticle core.

28. (canceled)

29. The method of claim 26, wherein the nanoparticle core precursor composition comprises first and second core precursor species containing ions to be incorporated into the growing nanoparticle core, the first and second core precursor species being combined in a single entity contained in the core precursor composition.

30. The method of claim 25, wherein formation of the layer comprising the second material comprises effecting conversion of a second material precursor composition to the second material.

31. The method of claim 30, wherein the second material precursor composition comprises third and fourth ions to be incorporated into the layer comprising the second material, the third and fourth ions being separate entities contained in the second material precursor composition.

32. (canceled)

33. The method of claim 30, wherein the second material precursor composition comprises third and fourth ions to be incorporated into the layer comprising the second material, the third and fourth ions being combined in a single entity contained in the second material precursor composition.

34. The method of claim 25, wherein the first material is the semiconductor material incorporating ions from groups 13 and 15 of the periodic table and the second material is the metal oxide.

35. The method of claim 30, wherein the second material precursor composition comprises the metal ions and the oxide ions to be incorporated into the layer comprising the metal oxide.

36. The method of claim 30, wherein the second material precursor composition contains a metal carboxylate compound comprising metal ions to be incorporated into the layer comprising the metal oxide material, and the conversion comprises reacting the metal carboxylate compound with an alcohol compound.

37. The method of claim 25, wherein the metal is selected from group 8 of the periodic table.

38. The method of claim 37, wherein the metal is iron.

39. The method of claim 25, wherein the metal is selected from group 12 of the periodic table.

40. The method of claim 39, wherein the metal is zinc.

41. A nanoparticle comprising:
a core that itself comprises a first material; and
thereover, a layer that comprises a second material,
wherein one of the first and second materials is a semiconductor material and the other of the first and second materials is a metal oxide material incorporating metal ions selected from any one of groups 1 to 12, 14, and 15 of the periodic table.

42. The nanoparticle of claim 41, wherein the metal is selected from any of groups 5 to 10 of the periodic table.

43-44. (canceled)

45. The nanoparticle of claim 41, wherein the metal is selected from group 8 of the periodic table.

46. (canceled)

47. The nanoparticle of claim 45, wherein the group 8 metal is iron.

48. The nanoparticle of claim 47, wherein the iron oxide has a formula selected from the group consisting of FeO, Fe₂O₃, and Fe₃O₄.

49. The nanoparticle of claim 48, wherein the iron oxide is γ-Fe₂O₃.

50. The nanoparticle of claim 41, wherein the semiconductor material incorporates ions selected from at least one of groups 2 to 16 of the periodic table.

51. (canceled)

52. The nanoparticle of claim 50, wherein the ions include at least one member of the group consisting of zinc, cadmium, and mercury.

53. The nanoparticle of claim 50, wherein the ions include at least one member of the group consisting of boron, aluminium, gallium, and indium.

54. (canceled)

55. The nanoparticle of claim 50, wherein the ions include at least one member of the group consisting of sulfur, selenium, and tellurium.

56. The nanoparticle of claim 50, wherein the ions include at least one member of the group consisting of phosphide, arsenide, and nitride.

57. (canceled)

58. The nanoparticle of claim 41, wherein the semiconductor material incorporates ions selected from the group consisting of ions from the transition metal group of the periodic table or ions from the d-block of the periodic table.

59. The nanoparticle of claim 41, further comprising a layer of a third material disposed between the nanoparticle core and the layer comprising the second material.

60. The nanoparticle of claim 41, wherein the first material is the semiconductor material and the second material is the metal oxide.

61. A method for producing a nanoparticle comprising a core that comprises a first material and, thereover, a layer that comprises a second material, wherein one of the first and second materials is a semiconductor material and the other of the first and second materials is an oxide of a metal selected from any of groups 3 to 10 of the periodic table, the method comprising the steps of:
forming the core; and
thereupon depositing, on the core, the layer comprising the second material.

62. The method of claim 61, wherein the core has a composition, formation of the core comprising (i) effecting conversion of a nanoparticle core precursor composition to the composition of the nanoparticle core, and (ii) growing the core.

63. The method of claim 62, wherein the precursor composition comprises first and second core precursor species containing ions to be incorporated into the growing nanoparticle core, the first and second core precursor species being separate entities in the core precursor composition, the conversion being effected in the presence of a molecular cluster compound under conditions permitting seeding and growth of the nanoparticle core.

64. (canceled)

65. The method of claim 62, wherein the precursor composition comprises first and second core precursor species containing ions to be incorporated into the growing nanoparticle core, the first and second core precursor species being combined in a single entity contained in the core precursor composition.
